(19) United States
(12) Patent Application Publication
(10) Pub. No.: US 2015/0130007 A1
(43) Pub. Date: May 14, 2015

(54) SEMICONDUCTOR DEVICE, AND METHOD FOR FORMING THE SAME

(71) Applicant: Renesas Electronics Corporation, Kawasaki-shi (JP)

(72) Inventor: Takeshi KAWAMURA, Kanagawa (JP)

(73) Assignee: RENESAS ELECTRONICS CORPORATION

(21) Appl. No.: 14/536,589

(22) Filed: Nov. 8, 2014

(30) Foreign Application Priority Data
Nov. 8, 2013 (JP) 2013-231655

(51) Int. Cl. H01L 27/146

(52) U.S. Cl. CPC H01L 27/14621; H01L 27/14627
USPC 257/432; 438/70

(57) ABSTRACT

A semiconductor device is improved in performance by preventing the generation of color mixing in its pixels which form an image pickup device. In a region between adjacent pixels, which is a region for separating regions where respective color filters of the pixels from each other, septum walls are formed. The septum walls are each made of an insulator film smaller in refractive index than the color filters, and an insulator film which is formed to cover side walls of the insulator film and is larger in refractive index than the color filters. In this way, a light ray radiated into the upper surface of each of the septum walls can be prevented from invading the pixels adjacent to the wall.

### CROSS-REFERENCE TO RELATED APPLICATIONS

The disclosure of Japanese Patent Application No. 2013-231655 filed on Nov. 8, 2013 including the specification, drawings, and abstract is incorporated herein by reference in its entirety.

### BACKGROUND

The present invention relates to a semiconductor device, and a method for manufacturing the device, and particularly to a technique applicable effectively to a semiconductor device, such as an image pickup device, and a method for manufacturing the device.

An image pickup device (imaging device) usable in a digital camera or some other has pixels arranged in a matrix form. In the pixels, photoelectric transducers are formed, respectively, these transducers being, for example, photodiodes of detecting light to generate electric charges. It is known that on each of the photodiodes, a color filter is located for delivering light having a specific color such as red, blue or green to the photodiode. It is known to form septum walls made of a material smaller in refractive index than the color filters, as a structure for preventing color mixing caused by the invasion of light into specific one of the pixels from the pixels adjacent thereto, between all adjacent color filters.

Patent Literature 1 (Japanese Unexamined Patent Application Publication No. 2011-258728) describes a structure in which between adjacent color filters, light shielding walls are located which are made to include a metal that does not transmit light, such as Al (aluminum). Patent Literature 1 never describes a specific method for manufacturing the light shielding walls.

Patent Literature 2 (Japanese Unexamined Patent Application Publication No. 2007-220832) states that plural films are stacked onto each other in a direction along a main surface of a semiconductor substrate to form light shielding walls, thereby preventing the color mixing defined above. This literature describes, as examples of the raw material of a film which forms the light shielding walls, silicon oxide, silicon nitride, and others. However, the literature does not refer to any relationship between positions thereof, or any relationship between the refractive indexes thereof.

### CITATION LIST

### Patent Literatures

Patent Literature 1:
Japanese Unexamined Patent Application Publication No. 2011-258728
Patent Literature 2:
Japanese Unexamined Patent Application Publication No. 2007-220832

### SUMMARY

In image pickup devices used in portable telephones and others, their pixels have been becoming finer in recent years, so that their septum walls have tended to become smaller. However, it is difficult that correspondingly to such a tendency, the film of their color filters is made thinner. Thus, it is desired to make the width of the septum walls small in the state of making the height of the septum walls consistent with the film thickness of the color filters. However, it is difficult to form septum walls having such a high aspect ratio. It is conceivable that the septum walls each needs to have a certain measure of width.

Light has a property that when the light advances from a medium large in refractive index into one small in refractive index, the light is totally reflected on the boundary between the media. By contrast, when light advances from a medium small in refractive index into one large in refractive index, the light is unlikely to be totally reflected.

In the case of forming septum walls, through which color filters are separated from each other, that is, light shielding walls, using silicon oxide or any other material smaller in refractive index than the color filters, color mixing between the adjacent pixels can be prevented when light is radiated from above the color filters of the pixels obliquely into the color filters to reach the septum walls (corresponding to the filters). This is because the light is totally reflected on the septum walls in light of a refractive index relationship between the septum walls and the color filters. In this case, however, when light radiated into the silicon oxide film from the upper surface of any one of the septum walls reaches the boundary between the septum wall and the corresponding color filter, total reflection is not caused in light of the above-mentioned refractive index relationship, so that the light invades the inside of the color filter.

In this case, from the outside of a region just above the specific pixel, the light invades the pixel, so that color mixing is caused. Thus, a correct output is not supplied from this pixel to cause a problem of lowering the performance of the semiconductor device.

An object of the present invention is to solve this problem. Other objects thereof and new features thereof will be made clear from the description of the present specification and the drawing attached thereto.

Typical ones out of aspects and embodiments of the present invention that are disclosed in the specification will be briefly described as follows:

A semiconductor device which is one of the typical aspects includes a semiconductor substrate, a photoelectric transducer formed in the semiconductor substrate, and a plurality of septum walls to sandwich a region where a color filer is formed just over the photoelectric transducer. Each of the septum walls includes a first film smaller in refractive index than the color filter, and a second film larger in refractive index than the color filter to cover side walls of the first film.

A method for manufacturing a semiconductor device, this method being another of the typical aspects, is a method including the following steps: the step of forming a first film smaller in refractive index than a color filter to sandwich a region where the color filter is to be formed in a pixel; and a subsequent step of forming a second film larger in refractive index than the color filter to cover side walls of the first film, thereby forming septum walls including the first and second film.

According to the aspects or embodiments disclosed in the specification, a semiconductor device to which any one of these disclosed contents is applied can be improved in performance. In particular, the generation of the above-defined color mixing can be prevented.

### BRIEF DESCRIPTION OF THE DRAWINGS

FIG. 1 is a sectional view illustrating a semiconductor device of Embodiment 1 of the present invention.

FIG. 2 is another sectional view illustrating the semiconductor device of Embodiment 1 of the invention.

FIG. 3 is a sectional view illustrating a step in a method for manufacturing the semiconductor device of Embodiment 1 of the invention.

FIG. 4 is a sectional view illustrating a step in the method after the step illustrated in FIG. 3.

FIG. 5 is a sectional view illustrating a step in the method after the step illustrated in FIG. 4.

FIG. 6 is a sectional view illustrating a step in the method after the step illustrated in FIG. 5.

FIG. 7 is a sectional view illustrating a step in the method after the step illustrated in FIG. 6.

FIG. 8 is a sectional view illustrating a step in the method after the step illustrated in FIG. 7.

FIG. 9 is a sectional view illustrating a step in the method after the step illustrated in FIG. 8.

FIG. 10 is a sectional view illustrating a step in the method after the step illustrated in FIG. 9.

FIG. 11 is a sectional view illustrating a step in the method after the step illustrated in FIG. 10.

FIG. 12 is a sectional view illustrating a step in the method after the step illustrated in FIG. 11.

FIG. 13 is a sectional view illustrating a semiconductor device of a modified example of Embodiment 1 of the invention.

FIG. 14 is a sectional view illustrating a step in a method for manufacturing a semiconductor device of Embodiment 2 of the invention.

FIG. 15 is a sectional view illustrating a step in the method after the step illustrated in FIG. 14.

FIG. 16 is a sectional view illustrating a step in the method after the step illustrated in FIG. 15.

FIG. 17 is a sectional view illustrating a step in the method after the step illustrated in FIG. 16.

FIG. 18 is a sectional view illustrating a step in the method after the step illustrated in FIG. 17.

FIG. 19 is a sectional view illustrating a step in the method after the step illustrated in FIG. 18.

FIG. 20 is a sectional view illustrating a step in the method after the step illustrated in FIG. 19.

FIG. 21 is a sectional view illustrating a step in the method after the step illustrated in FIG. 20.

FIG. 22 is a sectional view illustrating the semiconductor device of Embodiment 2 of the invention.

FIG. 23 is a sectional view illustrating a step in a method for manufacturing a semiconductor device of a modified example of Embodiment 2 of the invention.

FIG. 24 is a sectional view illustrating a step in the method after the step illustrated in FIG. 23.

FIG. 25 is a sectional view illustrating a step in the method after the step illustrated in FIG. 24

FIG. 26 is a sectional view illustrating a step in the method after the step illustrated in FIG. 25.

FIG. 27 is a sectional view illustrating the semiconductor device of the modified example of Embodiment 2 of the invention.

FIG. 28 is a sectional view illustrating a step in a method for manufacturing a semiconductor device of Embodiment 3 of the invention.

FIG. 29 is a sectional view illustrating a step in the method after the step illustrated in FIG. 28.

FIG. 30 is a sectional view illustrating a step in the method after the step illustrated in FIG. 29.

FIG. 31 is a sectional view illustrating a step in the method after the step illustrated in FIG. 30.

FIG. 32 is a sectional view illustrating a step in the method after the step illustrated in FIG. 31.

FIG. 33 is a sectional view illustrating a step in the method after the step illustrated in FIG. 32.

FIG. 34 is a sectional view illustrating a step in the method after the step illustrated in FIG. 33.

FIG. 35 is a sectional view illustrating a step in the method after the step illustrated in FIG. 34.

FIG. 36 is a sectional view illustrating a step in the method after the step illustrated in FIG. 35.

FIG. 37 is a sectional view illustrating a step in the method after the step illustrated in FIG. 36.

FIG. 38 is a sectional view illustrating a step in the method after the step illustrated in FIG. 37.

FIG. 39 is a sectional view illustrating a step in the method after the step illustrated in FIG. 38.

FIG. 40 is a sectional view illustrating the semiconductor device of Embodiment 3 of the invention.

FIG. 41 is a sectional view illustrating a step in a method for manufacturing a semiconductor device of Embodiment 4 of the invention.

FIG. 42 is a sectional view illustrating a step in the method after the step illustrated in FIG. 41.

FIG. 43 is a sectional view illustrating a step in the method after the step illustrated in FIG. 42.

FIG. 44 is a sectional view illustrating a step in the method after the step illustrated in FIG. 43.

FIG. 45 is a sectional view illustrating the semiconductor device of Embodiment 4 of the invention.

FIG. 46 is a sectional view illustrating a semiconductor device of a comparative example.

### DETAILED DESCRIPTION

Hereinafter, embodiments of the present invention will be described in detail with reference to the drawings. In all of the drawings referred to for describing the embodiments, the same reference number or sign is attached to each of members having the same function. Repeated description about the members is omitted. Moreover, in the embodiments described hereinafter, in principle, a repeated description about the same or similar partial structures or processes is not made unless especially needed.

In the present invention, any one out of plural light-receiving sections which are configured to form an image pickup device is called a pixel. Pixels are arranged in an array form to lay out a pixel region.

The present invention is characterized mainly by the structure of septum walls between color filters included in respective pixels, and a method for manufacturing the septum walls. Thus, about structures and manufacturing-methods of photodiodes included in the respective pixels, a peripheral circuit and others, detailed description is omitted in the embodiments described hereinafter.

### Embodiment 1

A semiconductor device of the present embodiment, and a method for manufacturing the device are characterized, particularly, by the structure of septum walls between color filters in an image pickup device, and a process for manufacturing the structure. The generation of color mixing in its pixels is prevented to make the light-receiving precision of the pixels high.

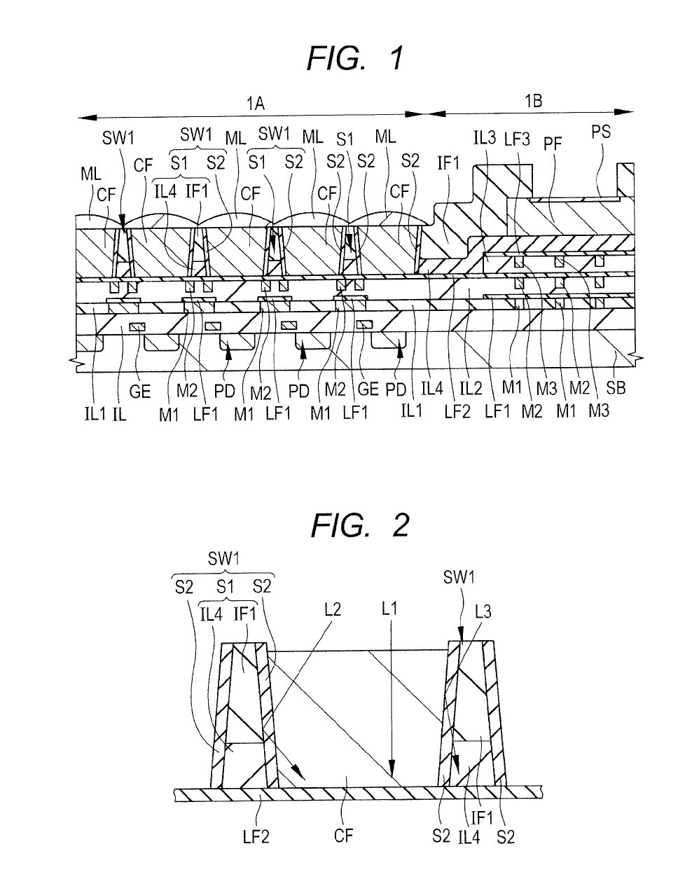

Hereinafter, the semiconductor device of the embodiment will be described with reference to FIG. 1. FIG. 1 is a cross section illustrating the image pickup device, which is the semiconductor device of the embodiment.

As illustrated in FIG. 1, the image pickup device of the embodiment has a semiconductor substrate SB made of, for example, monocrystal silicon. The semiconductor substrate SB has, on a main surface thereof, a pixel region 1A and a peripheral circuit region 1B. In other words, the pixel region 1A and the peripheral circuit region 1B are arranged along the main surface of the semiconductor substrate SB. The pixel region 1A is a region including plural pixels, which are light-receiving sections of the image pickup device. Being different therefrom, the peripheral circuit region 1B is not any light-receiving section, and is a region having, therein, low-breakdown-voltage transistors (not illustrated) used for, for example, switching and desired to operate at a high speed, interconnection layers thereon, and others.

In each of the pixels in the pixel region 1A, on the upper surface of the semiconductor substrate SB, a p-type semiconductor layer, into which a p-type impurity (for example, boron) is implanted, and an n-type semiconductor layer, in which an n-type impurity (for example, phosphorous or arsenic) is implanted, are formed. The p-type semiconductor layer is formed on the upper surface of the semiconductor substrate SB to have a smaller depth than the n-type semiconductor layer. The n-type semiconductor layer is formed just below the p-type semiconductor layer. The p-type semiconductor layer and the n-type semiconductor layer undergo pn junction to form photodiodes PD in the respective pixels.

The photodiodes PD are each a semiconductor element formed on the main surface of the semiconductor substrate SB, and each have a rectangular shape in plan view. The photodiode PD is a photoelectric transducer for generating signal electric charges in accordance with the quantity of light radiated into this transducer. In FIG. 1, the illustration of the shape of the regions of the p-type semiconductor is omitted. The pixels, each of which has the photodiode PD, are arranged in a longitudinal direction (y direction) and a transverse direction (x direction) along the upper surface of the semiconductor substrate SB. In short, the pixels are arranged in an array form in the pixel region 1A. The pixels referred to herein are each a region including one of the photodiodes PD on the upper surface of the semiconductor substrate SB, and further includes a region just above the photodiode PD and a region where a color filter that will be detailed later is formed.

Over the semiconductor substrate SB, gate electrodes GE made of, for example, a polysilicon film are formed to interpose, therebetween, a gate insulator film made of, for example, a silicon oxide film. The gate electrodes GE form respective gates of transferring transistors formed adjacently to the respective photodiodes PD formed in the pixel region 1A. The regions of the n-type semiconductor, in which the photodiodes PD are configured, are regions functioning as respective source regions of the transferring transistors.

The illustration of respective drain regions of the transferring transistors is omitted. The photodiodes PD are each coupled through one of the transferring transistors to an amplifying transistor for amplifying signals outputted from the photodiode PD, and other transistors. In FIG. 1, only the transferring transistors are illustrated. In the peripheral circuit region 1B, plural transistors and other semiconductor elements that form a peripheral circuit are formed. However, the illustration of these semiconductor elements is also omitted.

On the semiconductor substrate SB, an interlayer dielectric film IL is formed to cover the gate electrodes GE. The interlayer dielectric film IL is, for example, a silicon oxide film. The upper surface of the interlayer dielectric film IL is made flat. On the interlayer dielectric film IL in the pixel region 1A and the peripheral circuit region 1B, plural interconnections M1 are formed. The interconnections M1 are made mainly of, for example, Cu (copper). The interconnections M1 in the pixel region 1A (i.e., some of the interconnections M1) are formed between the adjacent pixels, and are each coupled through a contact plug (not illustrated) electrically to one of the semiconductor elements, such as the photodiodes PD or the transferring transistors. In the peripheral circuit region 1B, the other interconnections M1 are arranged to be lined up. These interconnections M1 are each coupled through a contact plug (not illustrated) electrically to one of the transistors formed on the semiconductor substrate SB in the peripheral circuit region 1B.

The interconnections M1 are buried in interconnection trenches opened in an interlayer dielectric film IL1 formed on the interlayer dielectric film IL. The interlayer dielectric film IL1 and the interconnections M1 form a first interconnection layer. The upper surface of the interconnections M1, and the upper surface of the interlayer dielectric film IL1 are at the same level to be made flat. An interlayer dielectric film IL2 is formed on the first interconnection layer. The interlayer dielectric films IL1 and IL2 are each, for example, a silicon oxide film. Between the interlayer dielectric film IL2 and the interconnections M1, a liner film LF1 is formed which is, for example, a SiC (silicon carbide) film or SiCN (silicon carbonitride) film.

Over the upper surface of the interlayer dielectric film IL2 in the pixel region 1A and the peripheral circuit region 1B, plural interconnection trenches are made to reach the middle of the depth of the interlayer dielectric film IL2. Inside the interconnection trenches, interconnections M2 made mainly of, for example, Cu (copper) are formed. The interconnections M2 in the pixel region 1A (i.e., some of the interconnections M2) are formed between the above-mentioned adjacent pixels, and are each coupled through a via (not illustrated) electrically to one of the interconnections M1 just below the interconnections M2. In the peripheral circuit region 1B, the other interconnections M2 are each coupled through a via (not illustrated) electrically to one of the interconnections M1 just below the interconnections M2. The individual vias are made of a conductor made mainly of Cu (copper), and formed to be integrated with the interconnections M2. The vias penetrate the interlayer dielectric film IL2 and the liner film LF1 to reach from the lower surface of the interconnections M2 to the upper surface of the interconnections M1. The interconnections M2, the interlayer dielectric film IL2, the liner film LF1, and the vias form a second interconnection layer.

The upper surface of the interconnections M2, and the upper surface of the interlayer dielectric film IL2 are at the same level to be made flat. In the peripheral circuit region 1B, an interlayer dielectric film IL3 is formed over the second interconnection layer to interpose a liner film LF2 therebetween. The liner film LF2 is, for example, a SiC (silicon carbide) film or SiCN (silicon carbonitride) film. The interlayer dielectric film IL3 is, for example, a silicon oxide film. In the same manner as the interlayer dielectric film IL2, the interlayer dielectric film IL3 in the peripheral circuit region 1B has interconnections M3 buried in plural trenches in the upper surface, respectively. The interconnections M3 are each coupled through a via electrically to one of the interconnections M2. In the peripheral circuit region 1B, the interconnections M3, the interlayer dielectric film IL3, the liner film LF2, and the vias form a third interconnection layer. The upper surface of the interconnections M3 and the upper surface of the interlayer dielectric film IL3 are at the same level to be made flat.

The interlayer dielectric film IL3 is not formed in the pixel region 1A. Over the third interconnection layer in the peripheral circuit region 1B, an interlayer dielectric film IL4 is formed to interpose a liner film LF3 therebetween. Over the second interconnection layer in the pixel region 1A, the interlayer dielectric film IL4 is formed to interpose the liner film LF2 therebetween. The interlayer dielectric film IL4 is, for example, a silicon oxide film and is, in the pixel region 1A, formed between the adjacent pixels. The liner film LF3 is, for example, a SiC (silicon carbide) film or SiCN (silicon carbonitride) film.

In the peripheral circuit region 1B, a pad PF made mainly of, for example, Al (aluminum) is formed on the interlayer dielectric film IL4. The pad PF is coupled electrically to the interconnections M3 through vias (not illustrated) which penetrate the interlayer dielectric film IL4 and the liner film LF3.

On the interlayer dielectric film IL4, an insulator film IF1 is formed to cover the upper surface of the interlayer dielectric film IL4 and a part of the pad PF. The insulator film IF1 is made of a material identical with that of the interlayer dielectric film IL4, and is, for example, a silicon oxide film. In the peripheral circuit region 1B, the upper surface of the pad PF is partially exposed in openings in the insulator film IF1. A metal oxide film PS is formed on the upper surface of the pad PF in the regions exposed from the insulator film IF1. The metal oxide film PS is a film formed through the step of oxidizing intentionally the metal (such as Al (aluminum)) which the pad PF is made of, that is, through passivating treatment.

In the pixel region 1A, the insulator film S1, which has a stacked structure made of the interlayer dielectric film IL4 and the insulator film IF1, is opened in each of the pixels and is in the form of walls around the pixel. The insulator film S1 is arranged between the adjacent pixels, and the photodiodes PD are arranged just below the respective openings in the insulator film S1. The insulator film S1 is, for example, a silicon oxide film. Side walls of the stacked film, which is made of the interlayer dielectric film IL4 and the insulator film IF1, that is, side walls of the insulator film S1 in the pixel region 1A are covered with an insulator film S2. In other words, in the pixel region 1A, the insulator film S2 covers inner side walls of the openings in the stacked film, which is made of the interlayer dielectric film IL4 and the insulator film IF1.

The side walls of the insulator film S1 come into directly contact with the insulator film S2. The insulator film S2 is a film larger in refractive index than the insulator film S1. When the insulator film S1 is, for example, a silicon oxide film, the insulator film S2 is a silicon nitride film, which is larger in refractive index than the silicon oxide film. The insulator film S1 and the insulator film S2 form septum walls SW1, which are light shielding walls. The septum walls SW1 each have a shape of a wall, and are arranged between the adjacent pixels. Just below the opening between the adjacent septum walls SW1, one of the photodiodes PD is arranged. In short, the photodiodes PD do not overlap with the septum walls SW1 in plan view. In other words, four of the septum walls SW1 are formed to sandwich the pixel including the region just above any one of the photodiodes PD.

The septum walls SW1 arranged to separate the pixels from each other are located to prevent light radiated obliquely into the main surface of the semiconductor substrate SB from invading, from any specific one of the pixels, the other pixels. In the present embodiment, the location of the septum walls SW1 prevents light from invading, from any specific one of the pixels, the pixels adjacent thereto to prevent the generation of color mixing when the present image pickup device picks up images.

The semiconductor device of the present embodiment has the above-mentioned structure. Over each of the pixels, the region between the adjacent septum walls around the pixel is a region where one out of color filters CF is formed. In short, just below the region where each of the color filters CF is formed, one of the photodiodes PD is arranged. The color filter CF is a film which transmits light rays in, for example, red, blue or green, and prevents the transmission of light rays in other colors through this filter. In other words, the color filter CF is a film which does not transmit light rays having wavelengths in a specific range but transmits light rays having wavelengths in the other ranges.

For example, the color filter CF formed in specific one of the pixels is a film which transmits light rays having a color different from respective colors of the color filters CF formed in the pixels adjacent to this specific pixel. In other words, out of the entire color filters CF, every two adjacent to each other through one of the septum walls SW1 transmit light rays different in color from each other. In FIG. 1, the entire color filters CF are formed in the region between the adjacent septum walls SW1 in a direction along the main surface of the semiconductor substrate SB.

As illustrated in FIG. 1, a micro-lens ML having, as its upper surface, a convex curved surface may be formed on each of the color filters CF. In other words, the micro-lens ML is a convex lens having light transparency, and has a function of condensing light through the color filter CF into the photodiode PD just below the color filter CF, the light being light radiated into each of the pixels from above the image pickup device, which is the semiconductor device of the present embodiment (that is, from the main surface side of the semiconductor substrate SB).

The image pickup device, which is the semiconductor device of the present embodiment, is a device of: converting, into an electric charge data, light radiated from the main surface side of the semiconductor substrate SB into each of the pixels in the pixel region 1A through the corresponding photodiode PD; and reading out the data to gain an image data or some other. The light is radiated through the upper surface of the corresponding color filter CF to penetrate the color filter CF, the interlayer dielectric films IL2, IL1 and LI to reach the photodiode PD.

In order for the image pickup device to gain a precise image, it is important, about specific one of the pixels (hereinafter referred to as the first pixel), that light radiated into any other pixel (hereinafter referred to as the second pixel) is prevented from invading the first pixel. In order for the image pickup device to gain a precise image, it is also important that light radiated into the region between the first and second pixel is prevented from invading the first or second pixel.

A reason therefor is as follows: from the viewpoint of the supply of a correct output from each of the photodiodes PD, light rays to be readout by the photodiode PD of the first pixel are only light rays radiated into the upper surface of the color filter CF just above this pixel; thus, light rays radiated into the other regions, which include the upper surface of the septum walls S1 around this pixel, should not be radiated into the photodiode PD of the first pixel. In conclusion, when light rays other than light rays radiated into the upper surface of the color filter CF of the first pixel are radiated into the photodiode PD of the first pixel, a correct output is not supplied from the photodiode PD of the first pixel.

In the present specification, a matter that as described above, any one of the photodiodes PD supplies an incorrect output is called color mixing, the supply being caused by the invasion of light rays into the first pixel from any one of the septum walls adjacent to the first pixel or from the second pixel. When color mixing is caused, light rays are radiated onto specific one of the pixels in a quantity larger than the quantity of light rays to be originally radiated, so that the pixel is raised in apparent sensitivity. Thus, with an incorrect sensitivity, an electric charge data is outputted. Accordingly, noises are easily generated into the resultant image data, so that correct image data cannot be obtained, using the image pickup device. Thus, a problem is caused that the semiconductor device is lowered in performance.

As a comparative example, in FIG. 46 is illustrated a cross section of a color filter CF of a pixel, and septum walls SWa arranged to sandwich the color filter. That is to say, FIG. 46 is a sectional view of a semiconductor device illustrated as the comparative example, and illustrates an enlarged structure of a region corresponding to any one of the color filters CF in FIG. 1 and the septum walls SW1 adjacent thereto. In FIG. 46, the illustration of a micro-lens ML on the color filter CF is omitted. In FIG. 46 are also illustrated incident light rays L1 and L2 radiated into the upper surface of the color filter CF, and an incident light ray L3 radiated into the upper surface of one of the septum walls SWa, these rays being each represented by an arrow. In FIG. 46, only one of all color filters CF is illustrated and the illustration of the other color filters CF is omitted.

The semiconductor device of the comparative example has the same structure as the semiconductor device illustrated in FIG. 1 except the structure of the septum walls SWa. In the same manner as the septum walls in, for example, FIG. 1, the septum walls SWa are located to include silicon oxide, and prevent a matter that light invades specific one of the pixels from the pixels adjacent thereto to cause color mixing. A difference of the septum walls SWa in the comparative example from the corresponding septum walls SW1 in the present embodiment illustrated in FIG. 1 is that the insulator film S2 illustrated in FIG. 1, which covers the side walls of the patterned insulator film S1, is not formed. In other words, the septum walls SWa are made only of an insulator film made of a material smaller in refractive index than the color filters CF adjacent thereto, and no film larger in refractive index than the septum walls SWa and the color filter CF is formed between the septum walls SWa and the color filter CF. In short, the color filter CF comes into directly contact with the septum walls SWa, which is smaller in refractive index than the color filter CF.

The incident light ray L1 illustrated in FIG. 46 is a light ray radiated perpendicularly into the main surface of the semiconductor substrate (not illustrated). The incident light ray L1 is radiated perpendicularly into the upper surface of the color filter CF of the single pixel illustrated in FIG. 46 to penetrate the color filter CF, and then reaches a photodiode (not illustrated) just below the color filter CF.

The incident light rays L2 and L3 are each a light ray radiated obliquely into the main surface of the semiconductor substrate. The incident light ray L2 is radiated obliquely into the upper surface of the color filter CF of the single pixel to pass in the color filter CF, and then reaches the boundary between the color filter CF and one of the septum walls SWa. When the color filter CF is compared with the septum walls SW, which is the silicon oxide film, the refractive index of the former is larger.

Light has a property that when the light advances from a medium large in refractive index into one small in refractive index, the light is totally reflected on the boundary between the media. By contrast, when light advances from a medium small in refractive index into one large in refractive index, the light is unlikely to be totally reflected.

In accordance with this property, the incident light ray L2 is totally reflected, on the boundary, toward the color filter CF side of the device. The thus reflected incident light ray L2 passes in the color filter CF to reach the photodiode just below the color filter CF. By locating the septum wall SWa, which is smaller in refractive index than the color filter CF, in this way, it is possible to prevent a matter than the incident light ray L2 radiated into the specific pixel invades the other pixels to cause color mixing.

The incident light ray L3 is a ray radiated obliquely into the main surface of the semiconductor substrate SB to be radiated into the upper surface of one of the septum walls SWa. The incident light ray L3 radiated from the upper surface of the septum wall SWa into the septum wall SWa passes in the septum wall SWa to reach the boundary between the color filter CF and the septum wall SWa. At this time, the incident light ray L3 passes through the boundary, without being totally reflected, to invade the inside of the color filter CF since the septum wall SWa is smaller in refractive index than the color filter CF. Accordingly, the incident light ray L3 enters, from the inside of the septum wall SWa, the color filter CF and then reaches the photodiode just below the color filter CF.

The incident light ray L3 is a light ray radiated not into the upper surface of the color filter CF but into the upper surface of the septum wall SWa. Thus, the light ray is a ray which the pixel should originally receive. Thus, when the incident light ray L3 passes in the septum wall SWa to invade the inside of the pixel to cause color mixing, the pixel receives a light quantity larger than the light quantity which the pixel should originally receive, so that the pixel is raised in apparent sensitivity. As a result thereof, a signal from the pixel is outputted with an incorrect sensitivity based on the extra light ray, so that an image data cannot be gained with an original sensitivity. By the sensitivity raised by the color mixing, noises are generated in the image data.

This problem is caused by the matter that the incident light ray L3 radiated into the upper surface of the septum wall SWa is received by the pixel adjacent to the septum wall SWa. Accordingly, as the width of the septum wall SWa is made larger to make the area of the upper surface of the septum wall Swa larger, the quantity of light rays radiated into the upper surface of the septum wall SWa becomes larger, so that the color mixing is more remarkably caused. The apparent sensitivity is also more remarkably raised.

When the width of the color filters CF is made small with a reduction in the size of the semiconductor device, it is desired to make the film thickness of the color filters CF small. However, the color filters CF need to have a film thickness sufficient for causing the color filters CF to transmit only a light ray in a specific color out of incident light rays. It is therefore difficult to make the film thickness small. Moreover, the septum walls SWa are members for separating the color filters CF from each other. Thus, unless the film thickness of the color filters CF becomes small, the height of the septum walls SWa cannot be made small. Accordingly, even when the semiconductor device is intended to be made fine, it is difficult to make the height of the septum walls SWa small. It is therefore necessary that when the width of the septum walls SWa is intended to be made small, the septum walls SWa are formed as a high and narrow film, that is, a film high in aspect ratio.

However, in the case of intending to form a film high in aspect ratio, a possibility that this film collapses while the semiconductor devices are each manufactured. Thus, the semiconductor devices may be unfavorably lowered not only in yield but also in reliability. It is therefore difficult to form the septum walls SWa with a high aspect ratio. As a result, in the case of making semiconductor devices finer, the width of their septum walls SWa needs to be kept, to some extent, large even when the area of their pixels is made smaller.

When it is difficult to form a film high in aspect ratio as described above, a reduction in the area of the pixels (concerned) makes the septum walls (concerned) larger in area than the pixels in plan view, so that a sensitivity-raise as described above, which is based on color mixing, is remarkably caused. It therefore becomes difficult that the image pickup device outputs more precise image data to cause a problem of a decline in the performance of the semiconductor device.

By contrast, as has been illustrated in FIG. 1, in the present embodiment, the septum walls SW1 are made of the patterned insulator film S1, which is the silicon oxide film, and the insulator film S2 covering the side walls of the insulator film S1. In FIG. 2 is illustrated a sectional view of a region of the semiconductor device of the embodiment, this region corresponding to the region illustrated in FIG. 46. That is to say, FIG. 2 is a sectional view of the semiconductor device of the embodiment, and illustrates an enlarged cross section of any one of the color filters and the septum walls adjacent thereto. In FIG. 2, incident light rays L1 and L2 radiated into the upper surface of the color filter CF, and an incident light ray L3 radiated into the upper surface of one of the septum walls SW1 are each represented by an arrow like FIG. 46. In FIG. 2 are illustrated only one of the color filters CF on the liner film LF2, and a pair of the septum walls SW1 located to sandwich the color filter CF. The illustration of the other color filters CF, micro-lenses and others is omitted.

As illustrated in FIG. 2, the incident light ray L1 radiated perpendicularly into the main surface of the semiconductor substrate SB (see FIG. 1) is radiated into the upper surface of the color filter CF to penetrate the color filter CF, and then reaches the photodiode PD (see FIG. 1) just below the color filter CF.

Next, the incident light ray L2 radiated obliquely into the main surface of the semiconductor substrate SB is radiated obliquely into the upper surface of the color filter CF to penetrate the color filter CF, and then reaches the boundary between the color filter CF and the insulator film S2. The insulator film S2, which is the silicon nitride film, is larger in refractive index than the color filter CF, so that the incident light ray L2 invades the inside of the insulator film S2 without being totally reflected in the boundary.

Thereafter, the incident light ray L2 passes in the insulator film S2 to reach the boundary between the insulator films S2 and S1. The insulator film S1, which is the silicon oxide film, is smaller in refractive index than the insulator film S2, which is the silicon nitride film, so that the incident light ray L2 is totally reflected to pass in the insulator film S1 and the color filter CF, and then reaches the photodiode PD just below the color filter CF. By locating the septum walls SW1 in this way, the incident light ray L2 radiated obliquely into the upper surface of the photodiode PD can be prevented from invading the pixels adjacent to the walls.

Next, the incident light ray L3 radiated obliquely into the main surface of the semiconductor substrate SB is radiated obliquely into the upper surface of the insulator film S1, which forms the septum walls SW1, and then penetrates the insulator film 51 to reach the boundary between the insulator films S1 and S2. The insulator film S2, which is the silicon nitride film, is larger in refractive index than the insulator film S1, which is the silicon oxide film, so that the incident light ray L3 invades the inside of the insulator film S2 without being totally reflected on the boundary.

Thereafter, the incident light ray L3 passes in the insulator film S2 to reach the boundary between the insulator film S2 and the color filter CF. Since the color filter CF is smaller in refractive index than the insulator film S2, which is the silicon nitride film, the incident light ray L3 is totally reflected on the boundary, and then passes in the insulator film S1 and the color filter CF to reach a region just below the septum walls SW1.

The region just below the septum walls SW1 is a region between the adjacent pixels; thus, no photodiode PD (see FIG. 1) is formed. In the region just below the septum walls SW1, the interconnections M2, which form the second interconnection layer illustrated in, e.g., FIG. 1, and the interconnections M1, which form the first interconnection layer, are formed. These interconnections are made of a metal material which does not transmit light. Accordingly, low is a possibility that the incident light ray L3 passes in the illustrated septum walls SW1 to invade the region just below the septum walls S1, and reaches the photodiode PD of the pixel adjacent to the walls.

As described above, in the present embodiment, between the side walls of the insulator film S1, which is smaller in refractive index than the color filter CF, and the side walls of the color filter CF, the insulator film S2, which is smaller in refractive index than the color filter CF, is formed. This manner makes it possible to prevent the following: the incident light ray L3 radiated through the upper surface of the septum walls SW1 into the septum walls SW1 invades, from the septum walls SW1, the color filter CF of the pixel adjacent to the septum walls SW1 to cause color mixing. Thus, the embodiment prevents the color mixing further than the comparative examples described with reference to FIG. 46.

In other words, it is possible to prevent a matter that a light ray radiated into a region other than the upper surface of the color filter CF of any one of the pixels invades the pixel so that the photodiode PD of the pixel receives an extra light ray. For this reason, in each of the pixels, an electric charge signal can be gained with a sensitivity to be originally obtained. Thus, the semiconductor device can be improved in performance.

Moreover, even when the septum walls SW1 are large in width to be large in area in plan view, it is possible to prevent a matter that the incident light ray L3 invades the pixel (concerned) to cause color mixing. Accordingly, in a case where the pixels are reduced in area in plan view, the generation of color mixing can be prevented even when the septum walls SW1 are made relatively large in width to avoid a rise in the aspect ratio of the septum walls SW1. Thus, even when the pixels are made small, for example, in order to make the semiconductor device finer, a correct output can be gained from the image pickup device. Thus, the semiconductor device can be improved in performance.

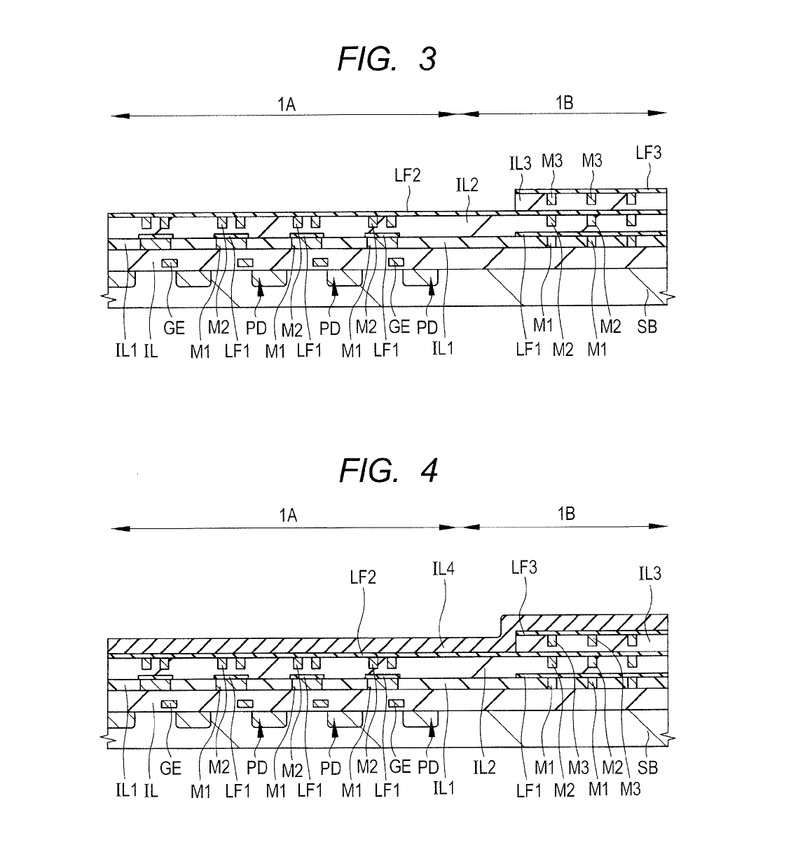

The following will describe a method for manufacturing the semiconductor device of the present embodiment with reference to FIGS. 3 to 12. FIGS. 3 to 12 are each a cross section illustrating the method for manufacturing the semiconductor device of the embodiment.

First, as illustrated in FIG. 3, a semiconductor substrate SB is provided which has, in a main surface thereof, a pixel region 1A and a peripheral circuit region 1B. Next, photodiodes PD, transferring transistors, amplifying transistors, and others are formed in the pixel region 1A of the main surface of the semiconductor substrate SB. In FIG. 3, the photodiodes PD are schematically illustrated, and gate electrodes GE of the transferring transistors are illustrated, but drain regions of the transferring transistors are not illustrated. Moreover, the amplifying transistors and other elements are not illustrated. In this step, the transistors and others (not illustrated) that form a peripheral circuit are formed in the peripheral circuit region 1B of the main surface of the semiconductor substrate SB.

The pixel region 1A has plural pixels in the form of a matrix arranged along a first direction along the main surface of the semiconductor substrate SB and a second direction that is orthogonal to the first direction and is along the main surface of the semiconductor substrate SB. One of the photodiodes PD is formed in each of the pixels.

Next, an interlayer dielectric film IL which is, for example, a silicon oxide film is formed on the semiconductor substrate SB by, for example, a chemical vapor deposition (CVD) method, so as to bury, into this film IL, the semiconductor elements formed near the upper surface of the semiconductor substrate SB through the above-mentioned step. Subsequently, a photographic technique and an etching method are used to pattern the interlayer dielectric film IL to make plural contact holes, and then a metal film is buried into the contact holes to make contact plugs (not illustrated) made of respective separate pieces of the metal film. At this time, the upper surface of the contact plugs and the upper surface of the interlayer dielectric film IL are made flat by, for example, a chemical mechanical polishing (CMP) method.

Next, for example, a CVD method is used to form an interlayer dielectric film IL1 which is, for example, a silicon oxide film. Subsequently, a photographic technique and an etching method are used to pattern the interlayer dielectric film IL1 to make plural interconnection trenches penetrating through the interlayer dielectric film IL1. Thereafter, the so-called single damascene method is used to form interconnections M1 made of, for example, Cu (copper), inside the respective interconnection trenches. The interconnections M1 are a metal film which does not transmit light. The interconnections M1 are electrically coupled through the contact plugs to the semiconductor elements on the main surface of the semiconductor substrate SB. The interlayer dielectric film IL1 and the interconnections M1 form a first interconnection layer.

In the pixel region 1A, the interconnections M1 are formed in the region between the adjacent pixels. A purpose of the formation is to prevent the following: when light is radiated onto the photodiode PD of each of the pixels from above the semiconductor substrate SB, the interconnections M1 shield the light. The upper surfaces of interconnections M1 and the interlayer dielectric film IL1 are made flat by, for example, a CMP method.

Next, an insulator film which is, for example, a SiC (silicon carbide) film or SiCN (silicon carbonitride) film is formed onto the interlayer dielectric film IL1 by, for example, a CVD method, and then the insulator film is patterned to form a liner film LF1. Thereafter, an interlayer dielectric film IL1 which is, for example, a silicon oxide film is formed onto the liner film LF1 by, for example, a CVD method. The liner film LF1 has a function of preventing metal atoms inside the interconnections M1 from diffusing to the inside of, for example, the interlayer dielectric film IL2. For this reason, inside the pixel region 1A, in its portion being in contact with the upper surface of the interconnections M1, the liner film LF1 is formed while the liner film LF1 is not formed just above the photodiodes PD.

Next, the so-called dual damascene method is used to form interconnections M2 buried into interconnection trenches in the upper surface of the interlayer dielectric film IL2, and vias (not illustrated) through which the interconnections M1 are coupled to the corresponding interconnections M2, respectively. Specifically, a photolithographic technique and an etching method are used to make plural interconnection trenches in the upper surface of the interlayer dielectric film IL1, and further below the bottom surface of these interconnection trenches, via holes are made which penetrate through the interlayer dielectric film IL1. Thereafter, for example, a Cu (copper) film is buried into the interconnection trenches and the via holes to form the interconnections M1 inside the respective interconnection trenches, and respective vias inside the via holes. The upper surface of the interconnections M2 and that of the interlayer dielectric film IL2 are made flat by, for example, a CMP method. The interlayer dielectric film IL2, the liner film LF1, the vias and the interconnections M2 form a second interconnection layer.

In the pixel region 1A, the interconnections M2 are formed between the adjacent pixels, but are not formed just above the photodiodes PD. This matter prevents light radiated into the respective photodiodes PD of the pixels from being shielded by the interconnections M2.

Next, for example, a SiC (silicon carbide) film or SiCN (silicon carbonitride) film is formed onto the interlayer dielectric film IL1 by, for example, a CVD method, so as to form a liner film LF2. Thereafter, an interlayer dielectric film IL3 which is, for example, a silicon oxide film is formed onto the liner film LF2 by, for example, a CVD method. Next, the so-called dual damascene method is used to form interconnections M3 buried in interconnection trenches in the upper surface of the interlayer dielectric film IL3, and vias through which the interconnections M3 are coupled to the corresponding interconnections, respectively, just below the interconnections M3. The interlayer dielectric film IL3, the liner film LF2, the vias and the interconnections M3 form a third interconnection layer. The interconnections M3 and the vias are formed in the same way as used to form the interconnections M2 and the vias which form the second interconnection layer.

Next, for example, a SiC (silicon carbide) film or SiCN (silicon carbonitride) film is formed onto the interlayer dielectric film IL3 by, for example, a CVD method, so as to form a liner film LF3. Subsequently, a photolithographic technique and an etching method are used to remove the liner film LF3 and the interlayer dielectric film IL3 inside the pixel region 1A. At this time, in the peripheral circuit region 1B, the interlayer dielectric film IL3, the liner film LF3 and the interconnections M3 are not removed. Through the step of the etching, the upper surface of the liner film LF2 of the pixel region 1A is made exposed. In this way, a structure illustrated in FIG. 3 is yielded.

Next, as illustrated in FIG. 4, for example, a CVD method is used to form an interlayer dielectric film IL4 which is, for example, a silicon oxide film onto the entire upper surface of the semiconductor substrate SB. The interlayer dielectric film IL4 comes into contact with the upper surface of the liner film LF2 of the pixel region 1A, and further comes into contact with the upper surface of the liner film LF3 in the peripheral circuit region 1B to cover the third interconnection layer in the peripheral circuit region 1B.

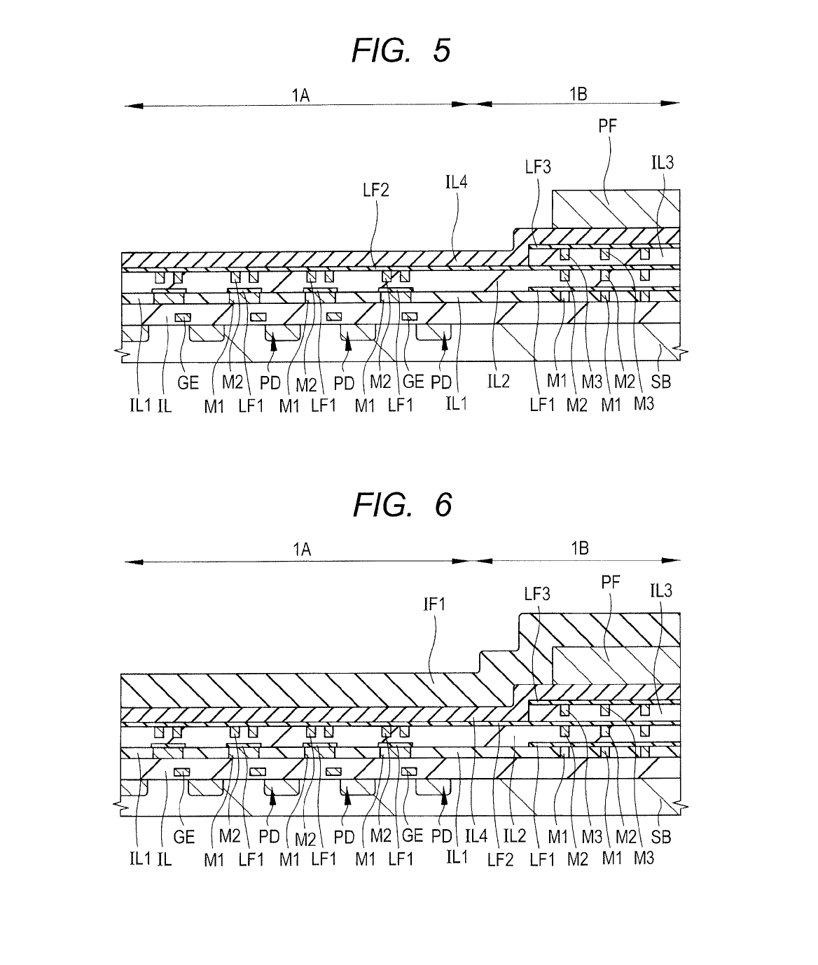

Next, as illustrated in FIG. 5, for example, a sputtering method is used to form a metal film larger in thickness than the interconnections M3 over the semiconductor substrate SB. The metal film is made of, for example, Al (aluminum). Thereafter, a photolithographic technique and an etching method are used to pattern the metal film, thereby removing the metal film in the pixel region 1A and further forming a pad PF made of the metal film onto the third interconnection layer in the peripheral circuit region 1B. The pad PF is illustrated as the aluminum film; however, the pad PF may be made of a metal film in which titanium nitride, aluminum and titanium nitride are successively stacked onto each other.

Next, as illustrated in FIG. 6, for example, a CVD method is used to form an insulator film IF1 which is, for example, a silicon oxide film onto the entire upper surface of the semiconductor substrate SB. The insulator film IF1 is a passivation film which comes into contact with the upper surface of the interlayer dielectric film IL4 in the pixel region 1A to cover the pad PF in the peripheral circuit region 1B. The insulator film IF1 and the interlayer dielectric film IL4 are made of the same material.

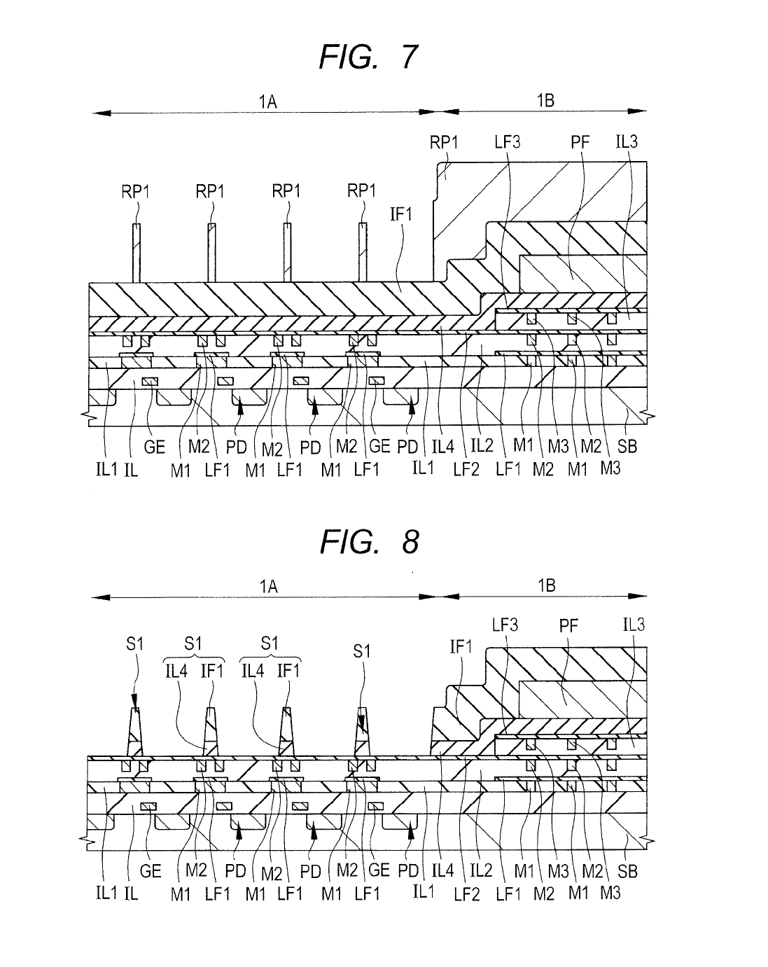

Next, as illustrated in FIG. 7, a resist pattern RP1 is formed onto the insulator film IF1. The resist pattern RP1 is a film from which each of the pixels in the pixel region 1A is made exposed, and is also a film covering the region between the adjacent pixels. The resist pattern RP1 also covers the whole of the peripheral circuit region 1B.

Next, as illustrated in FIG. 8, the resist pattern RP1 is used as a mask to perform dry etching, thereby removing the insulator film IF1 and the interlayer dielectric film IL4 of each of the pixels in the pixel region 1A. In this way, the upper surface of the liner film LF2 of each of the pixels is exposed, and further the resist pattern RP1 is removed. In other words, through this step, the insulator film IF1 and the interlayer dielectric film IL4 are selectively removed to make the photodiode PD of each of the pixels exposed from the insulator film IF1 and the interlayer dielectric film IL4. At this time, neither the insulator film IF1 nor the interlayer dielectric film IL4 is removed between the adjacent pixels, so that these films remain in a wall form on the liner film LF2. Additionally, in the peripheral circuit region 1B, the insulator film IF1 and the interlayer dielectric film IL4 also remain without being removed.

The stacked film made of the insulator film IF1 and the interlayer dielectric film IL4 that remain between the pixels through this step forms an insulator film S1, which is the silicon oxide film. The insulator film S1 is formed to sandwich regions in a direction along the main surface of the semiconductor substrate SB, these regions being regions where color filters are to be formed, respectively, in a subsequent step.

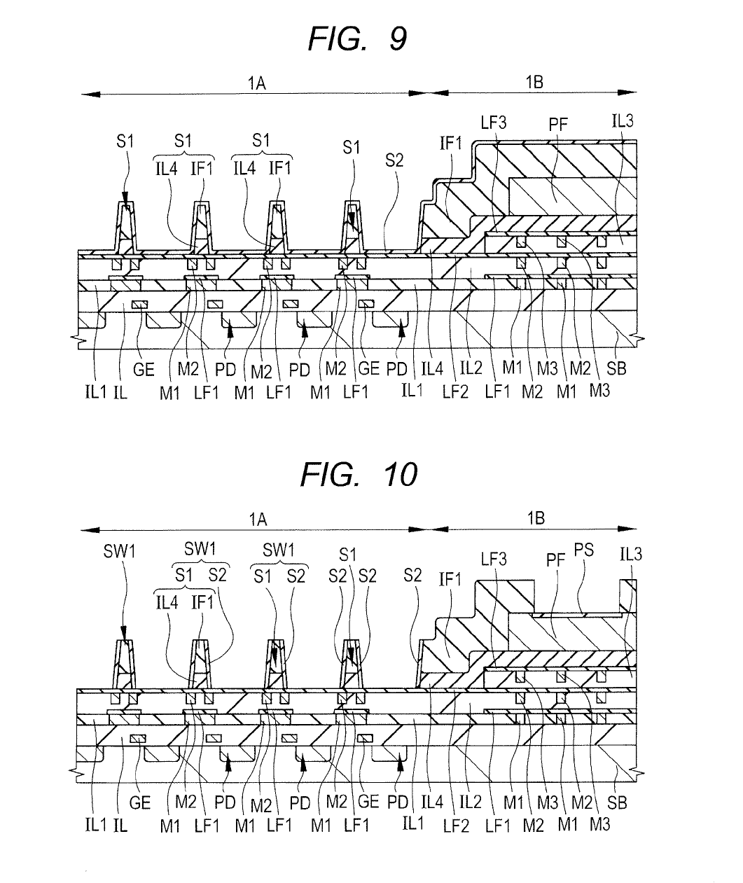

Next, as illustrated in FIG. 9, for example, a CVD method is used to form an insulator film S2 which is, for example, a silicon nitride film onto the entire upper surface of the semiconductor substrate SB. The insulator film S2 covers side walls and the upper surface of the insulator film S1 and the upper surface of the liner film LF2 of the individual pixels in the pixel region 1A. The insulator film S2 also covers the upper surface of the insulator film IF1 in the peripheral circuit region 1B. The insulator film S2 is formed to have a thickness of 20 to 30 nm, and is not completely buried into the region between all adjacent regions of the insulator film S1. The insulator film S2 is a film larger in refractive index than the insulator film S1.

Next, as illustrated in FIG. 10, dry etching is performed to remove the insulator film S2 partially. In this way, the upper surface of the liner film LF2 of each of the pixels, the upper surface of the insulator film S1, and the insulator film IF1 in the peripheral circuit region 1B are each exposed. The insulator film S2 being in contact with the side walls of the insulator film S1 is not removed so that each of the side walls of the wall-form insulator film S1, which are located at both sides of the film S1, is covered with the insulator film S2. In short, the insulator film S2 remains in the form of side walls on the side walls of the insulator film S1. In other words, the insulator film S2 is formed between the regions where the color filters are to be afterward formed, and the insulator film S1 adjacent to the regions.

The insulator film S1, and the insulator film S2 being in contact with the both side walls the insulator film S1 form septum walls SW1. The septum walls SW1 are formed into the form of walls between the adjacent pixels in the pixel region 1A. Through the step for the above-mentioned etching, the upper surface of the liner film LF2 of each of the pixels is exposed so that the insulator film S2 is not formed between the individual septum walls SW1. Regions which are over the liner film LF2 in the pixel region 1A and are regions between the adjacent septum walls SW1 are the regions where the color filters, which will be detailed later, are to be formed. In short, the photodiodes PD are arranged just below the regions where the color filters are to be formed. In other words, the insulator films S1 and S2 which form the septum walls SW1 are the regions which are just above the photodiodes PD and are formed so as to sandwich the regions where the color filters are to be afterward formed.

Thereafter, a photolithographic technique and an etching method are used to remove the insulator film IF1 in the peripheral circuit region 1B partially, thereby making the upper surface of the pad PF exposed. When the titanium nitride film is stacked on the aluminum film, which partially forms the pad PF, the titanium nitride film is removed by the etching, so that the aluminum film is exposed.

Subsequently, passivation treatment is performed to form a metal oxide film PS on the pad PF upper surface exposed from the insulator film IF1. The metal oxide film PS is made of, for example, aluminum oxide (Al₂O₃). By subjecting the photodiode PD surface intentionally to the passivation treatment in this way, the photodiodes PD are oxidized so that the film quality of the photodiodes PD can be prevented from becoming unstable. For the passivation treatment, for example, the following is usable: a method of treating with a strong oxidizer such as nitric acid, or a method of heating in an atmosphere containing oxygen.

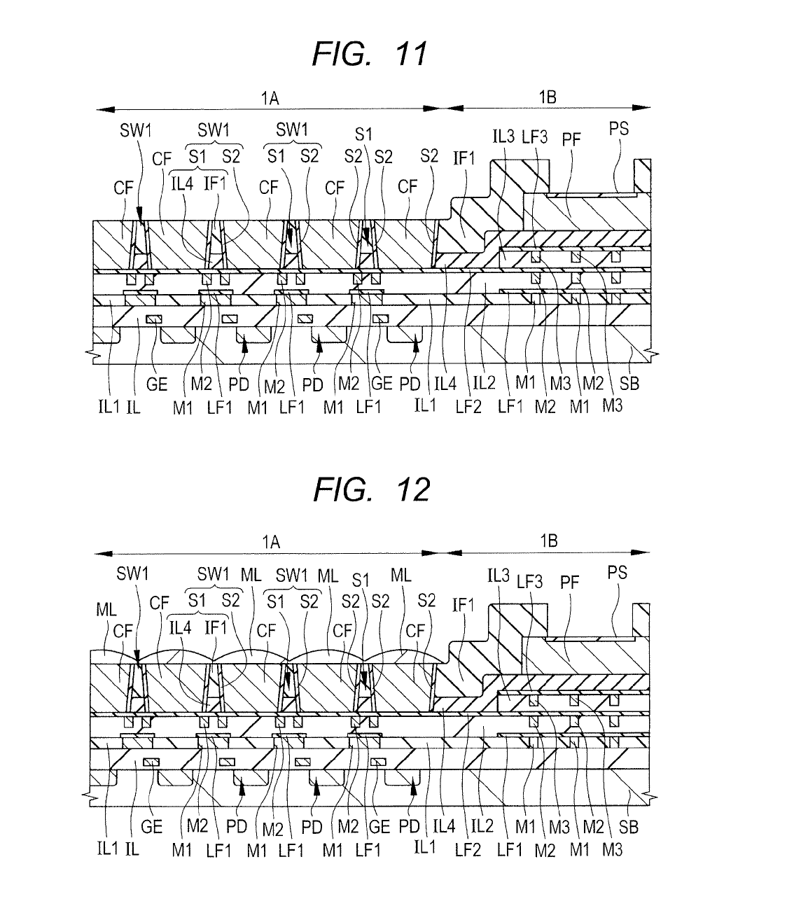

Next, as illustrated in FIG. 11, for the individual pixels, the color filters CF are formed, respectively, in the regions between the adjacent septum walls SW1. When the color filters CF are formed to be of different species, that is, to have different colors for pixels adjacent to any one of the pixels, the different-species color filters CF are formed by lithographic technique. In this embodiment, for example, red color filters out of the color filters CF are formed for specific ones of the pixels. For a pixel adjacent to any one of the specific pixels, a blue, green or colorless color filter CF, out of the filers CF, is formed. The red, blue or green color filter CF is made of a film which transmits specific light rays.

The bottom surface of the color filter CF of each of the pixels comes into contact with the upper surface of the liner film LF2, and side walls of the color filter CF come into contact with the side walls of the insulator film S2. The color filters CF are formed to have, for example, an upper surface having a height substantially equal to that of the upper surface of the septum walls SW1. The refractive index of the color filters CF is larger than that of the insulator film S1 but smaller than that of the insulator film S2. The present embodiment is characterized in that the insulator film S2 larger in refractive index than the color filters CF is formed between the insulator film S1 smaller in refractive index than the color filters CF and the color filters CF.

Next, as illustrated in FIG. 12, micro-lenses ML are formed just above the color filters CF, respectively. The micro-lenses ML are each a convex lens, in which its upper surface is curved into a convex form, and are each made of a film which transmits light. In the pixel region 1A, the micro-lenses ML are formed in the pixels, respectively. The micro-lenses ML are formed, for example, by forming a film onto the color filters CF in the pixel region 1A, heating the film to be melted, and then making the color-filter-CF-corresponding upper surfaces of this film each round.

Through this process, the semiconductor device of the present embodiment is completed. Hereinafter, a description will be made about advantageous effects of the method for manufacturing the semiconductor device of the embodiment.

As has been described with reference to FIGS. 9 to 11, in the embodiment, the insulator film S2 is formed onto the side walls of the insulator film S1. By contrast, as has been described with reference to FIG. 46, in a case where the septum walls SWa are made only of an insulator film smaller in refractive index than the color filters CF, and when the incident light ray L3 is radiated into predetermined one of the septum walls SWa through the upper surface of the predetermined septum wall SWa, the incident light L3 invades the inside of the color filter CF of the pixel so that color mixing is caused.

In particular, in a case where the area of each of the pixels in plan view is made small to make the semiconductor device fine and further it is difficult to make the height of the color filers and the septum walls small, it is necessary that septum walls are each formed to have, to some extent, a large width in order to prevent the septum walls from collapsing in the step of working the insulator film, which has been described with reference to FIG. 8, or in a subsequent washing step and other steps.

In other words, from the viewpoint of preventing the collapse of septum walls, it is difficult that the septum walls are each formed with a high aspect ratio. Accordingly, in the case of making the area of each pixel in plan view small, it is difficult to make the area of each of the septum walls in plan view small. In this case, in the comparative example that has been illustrated in FIG. 46, the quantity of the incident light ray L3, which is radiated into the upper surface of predetermined one of the septum walls SWa and then received by any one of the photodiodes PD, is larger than that of the incident light rays L1 and L2, which are radiated into the upper surface of one of the color filters CF and then received by the photodiode PD, so that color mixing is remarkably caused. Thus, when a restraint of the generation of color mixing is intended in the semiconductor device of the comparative example, there is caused a problem that it is difficult to make the semiconductor device fine.

As has been described with reference to FIG. 2, in the present embodiment, the insulator film S2 larger in refractive index than the color filters CF is formed between the insulator film S1 larger in refractive index than the color filters CF, and the color filters CF. This manner prevents the incident light ray L3 radiated into the upper surface of the predetermined septum wall SW1 from invading the color filters CF adjacent to the predetermined septum wall SW1 to prevent the generation of color mixing.

Accordingly, even when the width of the individual septum walls SW1 is large so that the area of their region in plan view is large, the incident light ray L3 can be prevented from invading the pixels to cause color mixing. Thus, when the area of the pixels in plan view is made small, the generation of color mixing can be prevented even when the septum walls SW1 are formed to be relatively wide in order to avoid an increase in the aspect ratio of each of the septum walls SW1. In this way, a correct output can be gained from the image pickup device even when the pixels are made small. Thus, the semiconductor device can be improved in performance.

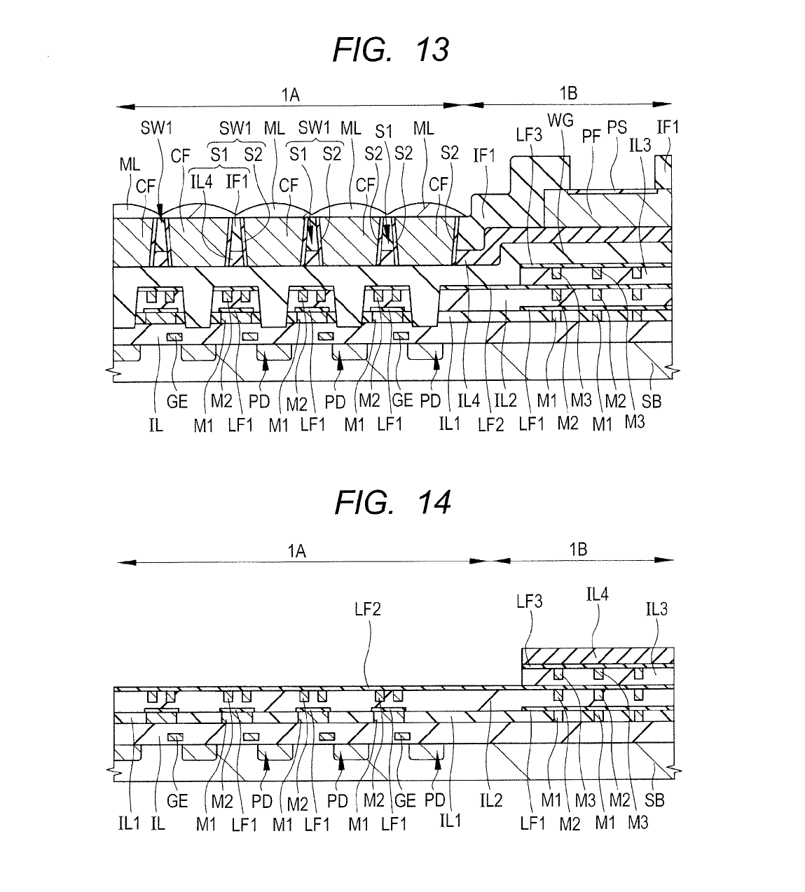

With reference to FIG. 13, a modified example of the semiconductor device of the present embodiment will be described. FIG. 13 is a sectional view illustrating an image pickup device of the modified example of the semiconductor device of the embodiment.

As illustrated in FIG. 13, the image pickup device of the modified example of the embodiment has substantially the same structure as the image pickup device described with reference to FIG. 1 except that an optical waveguide WG is formed. The optical waveguide WG is made to include a material which transmits light, and is, for example, a silicon nitride film. The optical waveguide WG is formed between a color-filter-CF-formed region in each pixel, and a photodiode PD of the pixel.

The optical waveguide WG is formed between the respective steps described with reference to FIGS. 3 and 4. Specifically, after the step described with reference to FIG. 3, a photolithographic technique and an etching method are used to remove, in the pixel region 1A, the liner film LF2 in each of the pixels, and the interlayer dielectric films IL2, IL1 and IL therein partially. In this way, in the pixel, a depression is formed which reaches from the upper surface of the liner film LF2 to the middle of the depth of the interlayer dielectric film IL.

Next, for example, a CVD method is used to form a silicon nitride film onto the semiconductor substrate SB, thereby burying the silicon nitride film into the depressions. In this way, the optical waveguide WG is formed which is the silicon nitride film. Thereafter, the steps described with reference to FIGS. 4 to 12, respectively, are performed to complete the semiconductor device of the modified example illustrated in FIG. 13. As has been illustrated in FIG. 13, the respective bottom surfaces of the septum walls SW1 and the color filters CF come into contact with the upper surface of the optical waveguide WG, and the optical waveguide WG is formed in the depression between the color filter CF and the photodiode PD of each of the pixels. Therein, light which has been condensed through the micro-lens ML concerned and transmitted through the color filter CF passes, through the optical waveguide WG and the interlayer dielectric film IL, to reach the photodiode PD.

In the present modified example, the refractive index of the optical waveguide WG is, for example, a relatively high value of about 1.97. In the image pickup device described with reference to FIGS. 1 to 12, the insulator film S2 is partially removed in the step described with reference to FIG. 10. However, in the case of arranging the optical waveguide WG in the present modified example or any equivalent example, it is unnecessary to perform the step of removing the insulator film S2, which has been described with reference to FIG. 10. In conclusion, the insulator film S2 (see FIG. 9) may remain on the bottom of the regions between the adjacent septum walls SW1, and on the septum walls SW1. In other words, in each of the pixels, the insulator film S2 may remain between the region where the color filter CF is formed, and the optical waveguide WG. In the figures concerned, illustration is not made about any structure of the image pickup device obtained when the insulator film S2 is caused to remain in this way without being removed.

When the insulator-film-S2-removing step described with reference to FIG. 10 is not performed as described above, the generation of noises can be prevented in data output from the image pickup device, by forming the insulator film S2 using a material equivalent in refractive index to that of the optical waveguide WG.

In a case where the upper surface of the septum walls SW1 is covered with the insulator film S2 and further even when a light ray is radiated into the upper surface of the septum walls SW1 equivalently to the incident light ray L3 illustrated in FIG. 2, the radiated-into light is totally reflected on the boundary between the insulator film S1 and the insulator film S2 (not illustrated) on the septum walls SW1, so that the radiated-into light can be prevented from being transmitted through the insulator film S1 to reach the photodiodes PD. Thus, color mixing can be prevented to improve the semiconductor device in performance.

Additionally, it is unnecessary to perform the insulator-film-S2-removing step described with reference to FIG. 10, so that the process for manufacturing the semiconductor device can be shortened. Accordingly, costs for manufacturing the semiconductor device can be decreased.

### Embodiment 2

With reference to FIGS. 14 to 22, a description will be made about a matter that the generation of color mixing caused by light transmitted through septum walls is prevented by rendering the septum walls partially a metal film. FIGS. 14 to 21 are each a cross section referred to for describing a method for manufacturing a semiconductor device of the present embodiment. FIG. 22 is a cross section illustrating an enlarged part of the semiconductor device of the embodiment.

In the process for manufacturing the semiconductor device of the embodiment, first, the same steps as described with reference to FIGS. 3 and 4 are performed. Next, as illustrated in FIG. 14, a photolithographic technique and an etching method are used to remove the interlayer dielectric film IL4 wholly in the pixel region 1A, thereby causing the interlayer dielectric film IL4 to remain only just over the third interconnection layer. Accordingly, in the pixel region 1A, only the upper surface of the liner film LF2 is made exposed.

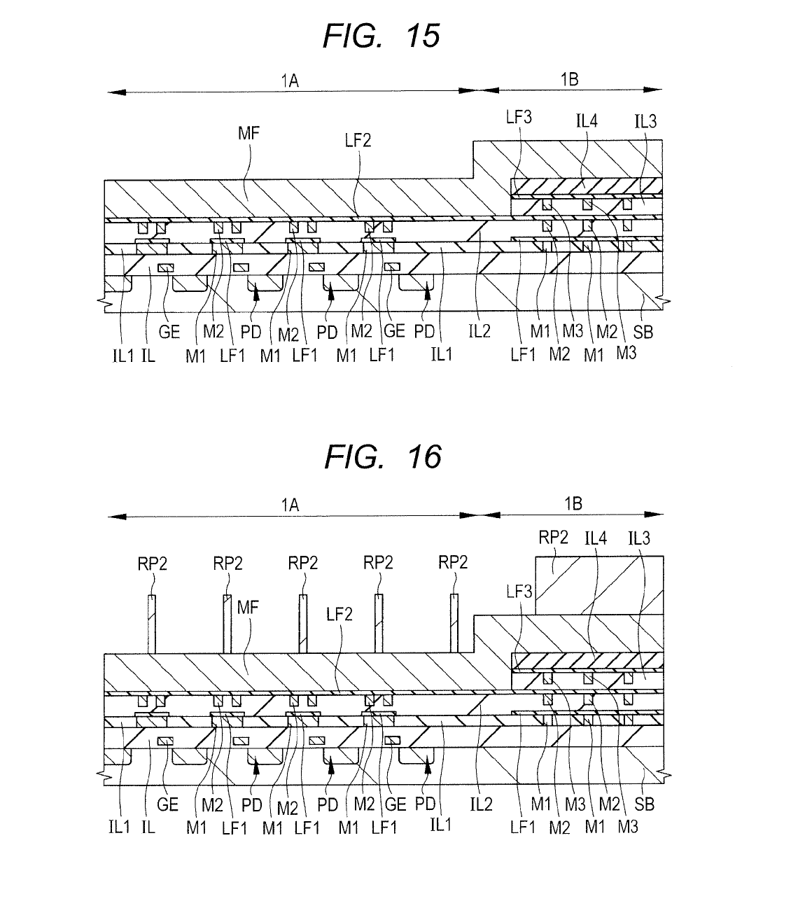

Next, as illustrated in FIG. 15, for example, a sputtering method is used to form a metal film MF on the semiconductor substrate SB. The metal film MF is, for example, an aluminum film.

Next, as illustrated in FIG. 16, a photolithographic technique is used to form a resist pattern RP2 on the metal film MF. The resist pattern RP2 is a film from which the individual pixels are exposed in the pixel region 1A, and is also a film covering region between the adjacent pixels. The resist pattern RP2 also covers a part of the upper surface of the metal film MF just over the interlayer dielectric film IL4.

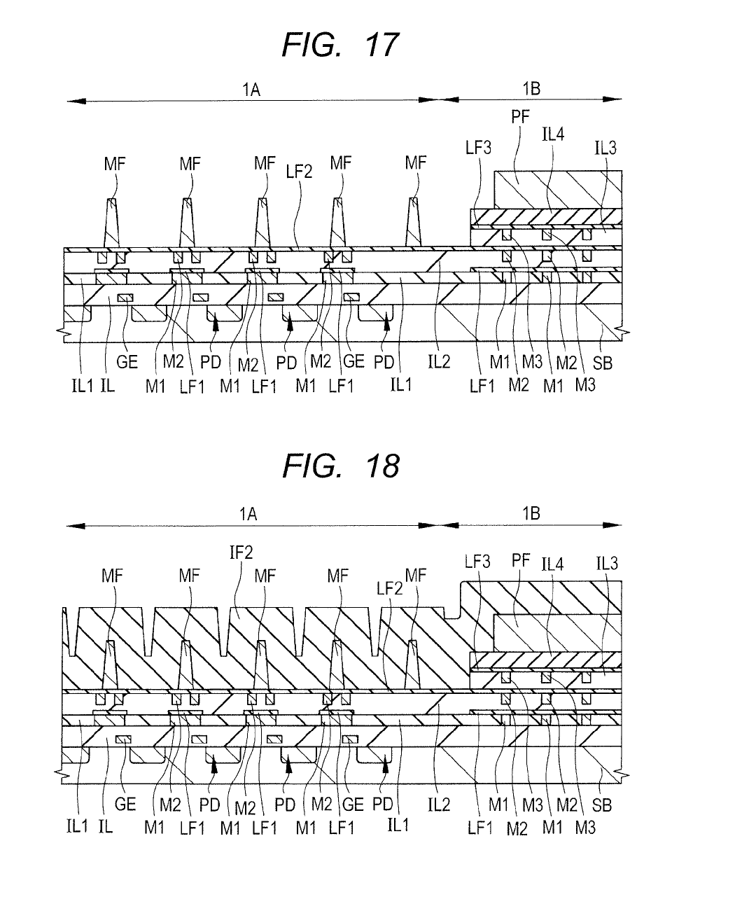

Next, as illustrated in FIG. 17, the resist pattern RP2 is used as a mask to perform etching, thereby making the upper surface of the liner film LF2 of each of the pixels exposed in the pixel region 1A. Thereafter, the resist pattern RP2 is removed. At this time, the metal film MF between the adjacent pixels is not removed to remain in a wall form on the liner film LF2. In other words, the patterned metal film MF is formed to sandwich, in a direction along the main surface of the semiconductor substrate SB, regions where color filters are to be formed in a subsequent step. A part of the metal film MF just over the interlayer dielectric film IL4 of the peripheral circuit region 1B also remains without being removed. In this way, a pad PF is formed which is made of the metal film MF remaining in the peripheral circuit region 1B.

Next, as illustrated in FIG. 18, for example, a CVD method is used to form an insulator film IF2 which is, for example, a silicon oxide film or silicon nitride film on the semiconductor substrate SB. The formation of the insulator film IF2 is attained to cover the metal film MF in the pixel region 1A, and the pad PF in the peripheral circuit region 1B.

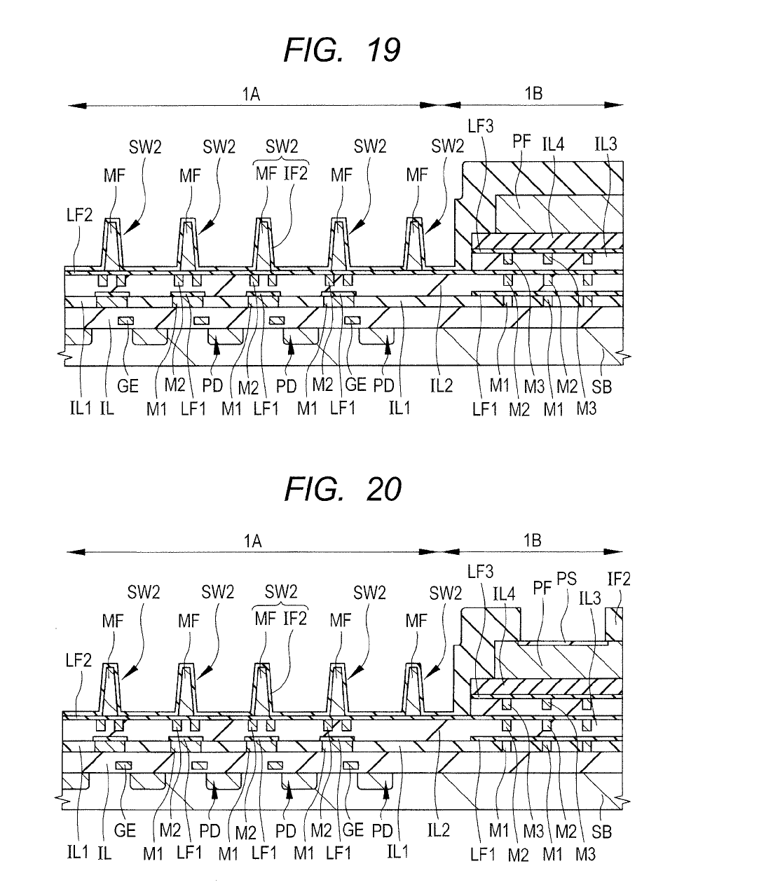

Next, as illustrated in FIG. 19, a photolithographic technique and an etching method are used to etch back the insulator film IF2 in the pixel region 1A to make this film thin. The etching is performed to cause the insulator film IF2 to remain with such a film thickness that the metal film MF in the pixel region 1A is not exposed. This manner makes the film thickness of the insulator film IF2 in the pixel region 1A smaller than that of the insulator film IF2 in the peripheral circuit region 1B. The insulator film IF2 is a film laid to cover the metal film MF to prevent the metal film MF from being oxidized into an unstable film.

The insulator film IF2 made thin in this step and the metal film ME covered with the insulator film IF2 form septum walls SW. In other words, in the pixel region 1A, the septum wall SW2 are formed in the form of walls between the adjacent pixels. Each of the septum walls SW2 formed in the pixel region 1A is made of the metal film MF, and the insulator film IF2 covering side walls and the upper surface of the metal film MF. The regions between the adjacent septum walls SW2 in a direction along the main surface of the semiconductor substrate SB are regions where the color filters are to be afterward formed. A purpose for making the insulator film IF2 thin is to enlarge the regions between the adjacent septum walls SW2, that is, the spaces where the color filters are to be formed.

Next, as illustrated in FIG. 20, the same step of making openings into the insulator film IF1 and the same step of performing passivating processing as described with reference to FIG. 10 are performed to form a metal oxide film PS on the upper surface of the pad PF which is exposed from the insulator film IF2.

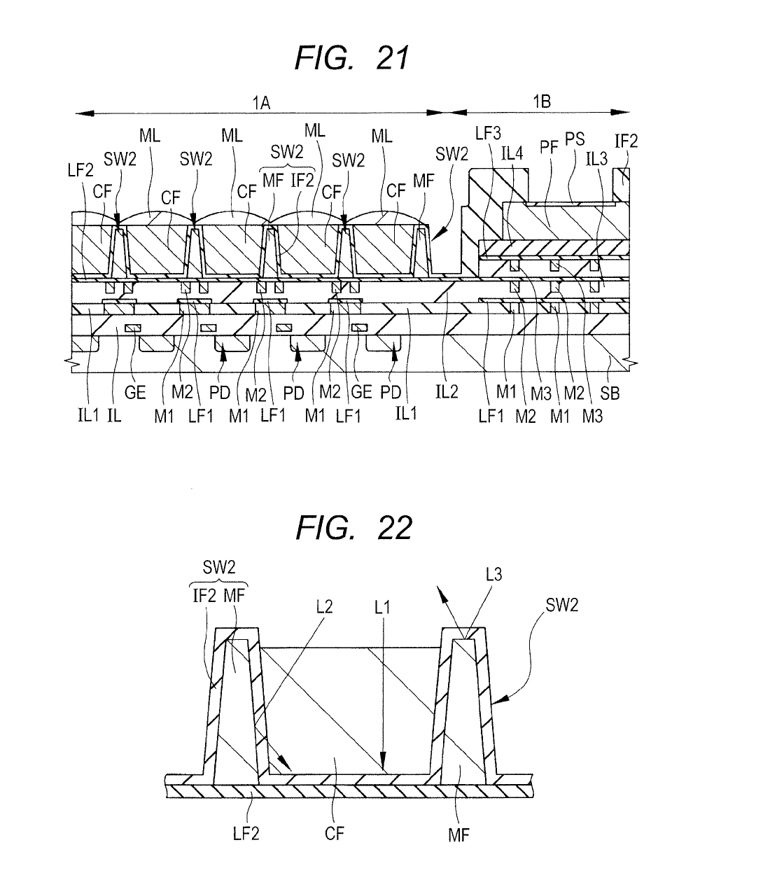

Next, as illustrated in FIG. 21, the same step as described with reference to FIGS. 11 and 12 is performed to form color filters CF between the adjacent septum walls SW. Thereafter, micro-lenses ML are formed on the color filters CF, respectively. Through this process, the semiconductor device of the present is completed.

In FIG. 22 is illustrated an enlarged cross section of one of the color filters CF and the respective septum walls SW2 at both sides of the color filter CF. In the same manner as in FIG. 2, in FIG. 22, incident light rays L1 to L3 are shown. The incident light ray L1 is radiated into the upper surface of the color filter CF to reach one of the photodiodes without being radiated into the septum walls SW2 around the color filter CF. The incident ray L2 is radiated into the upper surface of the color filter CF, and then reflected onto the side walls of the metal film MF, which forms the septum walls SW2, to reach the photodiode. In other words, the metal film MF, which forms the septum walls SW2, is a film which does not transmit light; thus, the incident light ray L2 is totally reflected onto the side walls of the metal film MF to reach the photodiode just below the color filter CF.

The incident light ray L3 is radiated into the upper surface of the septum walls SW2. The incident light ray L3 is totally reflected onto the upper surface of the metal film MF, which forms the septum walls SW2, not to be transmitted through the metal film MF. Therefore, the following possibility can be made lower in Embodiment 2 than in Embodiment 1: a possibility that light radiated into the upper surface of the septum walls is received by the photodiode PD of each of the pixels. This matter makes it possible to prevent the generation of color mixing to improve the semiconductor device in performance.

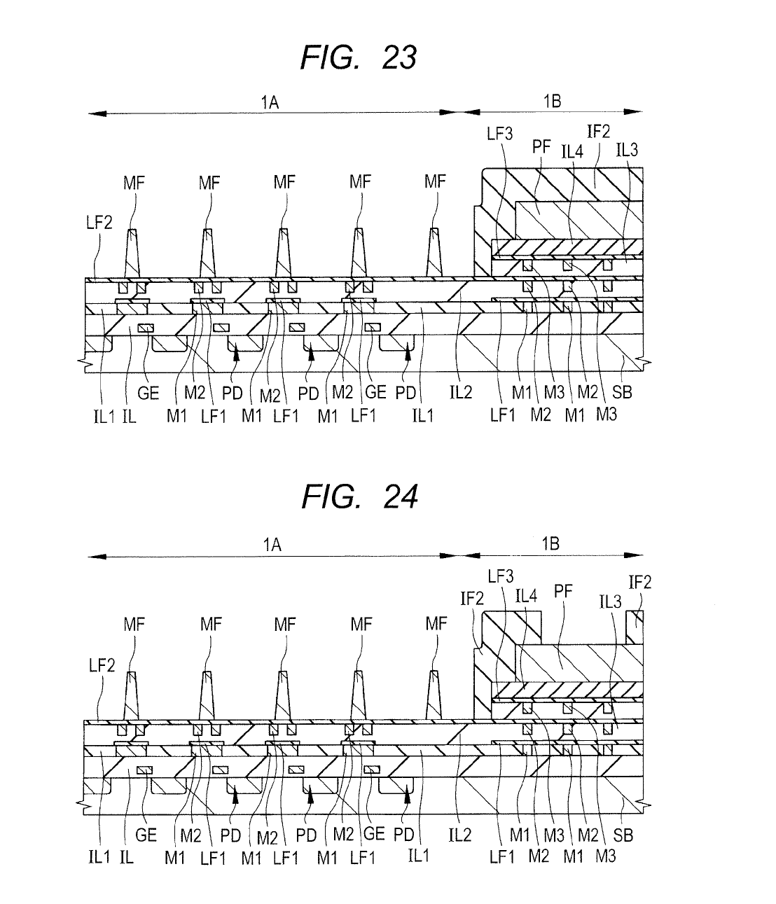

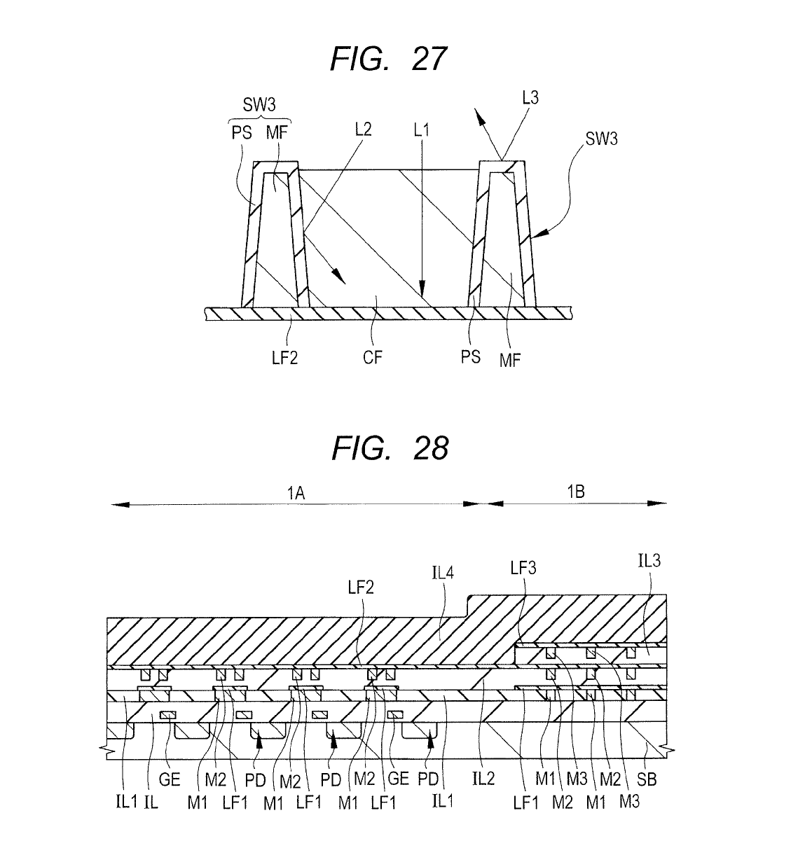

With reference to FIGS. 23 to 27, a modified example of the semiconductor device of the present embodiment will be described. FIGS. 23 to 26 are each a sectional view illustrating a method for manufacturing the semiconductor device, which is the modified example of the embodiment. FIG. 27 is a sectional view illustrating an enlarged part of this semiconductor device.

In the present modified example, first, the same steps as illustrated in FIGS. 3, 4 and 14 to 18 are performed. Thereafter, as illustrated in FIG. 23, a photolithographic technique and an etching method are used to remove the insulator film IF2 in the pixel region 1A. This manner makes the following exposed: the side walls of the metal film MF and the upper surface thereof in the pixel region 1A; and a part of the upper surface of the liner film LF2 therein.

Next, as illustrated in FIG. 24, a photolithographic technique and an etching method are used to make openings in the insulator film IF2 in the peripheral circuit region 1B, thereby making a part of the upper surface of the pad PF exposed.

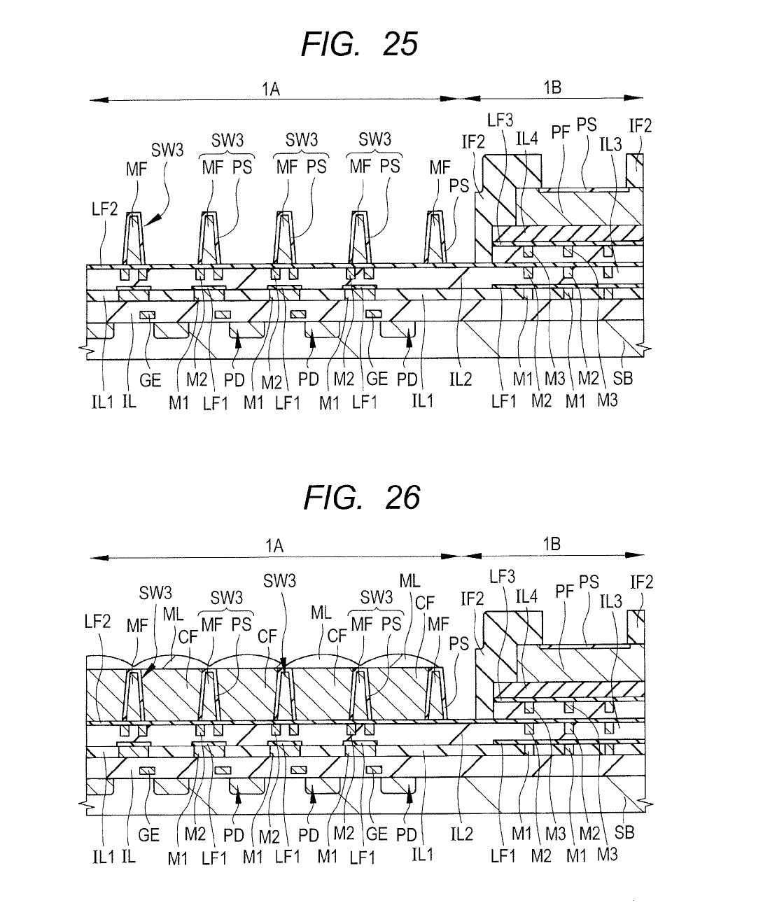

Next, as illustrated in FIG. 25, passivating processing is performed to oxidize the outer surface of the metal film MF in the pixel region 1A, and the upper surface of the pad PF, which is exposed from the insulator film IF2 in the peripheral circuit region 1B. In this way, the metal oxide film PS covers the side walls and the upper surface of the metal film MF in the pixel region 1A, and the upper surface of the pad PF, which is exposed from the insulator film IF2. The metal film MF in the pixel region 1A and the metal oxide film PS covering the metal film MF forms septum walls SW3.

Next, as illustrated in FIG. 26, the same steps as described with reference to FIGS. 11 and 12 are performed to form color filters CF between the adjacent septum walls SW3. Thereafter, a micro-lens ML is formed on each of the color filters CF. In this way, the semiconductor device of the modified example of the present embodiment is completed.

In FIG. 27 is illustrated an enlarged cross section of any one of the color filters CF and the respective septum walls SW3 at both sides of the color filter CF. In the same manner as in FIGS. 2 and 22, in FIG. 27, incident light rays L1 to L3 are illustrated. The incident light ray L1 is radiated into the upper surface of the color filter CF to reach one of the photodiodes without being radiated into the septum walls SW3. The incident ray L2 is radiated into the upper surface of the color filter CF, and then reflected onto side walls of the septum walls SW3 to reach the photodiode. In other words, the patterned metal film MF and the patterned metal oxide film PS, which form the septum walls SW3, reflect light totally; thus, the incident light ray L2 is totally reflected onto the side walls of the patterned metal oxide film PS to reach the photodiode just below the color filter CF.

The incident light ray L3 is radiated into the upper surface of the septum walls SW3. The incident light ray L3 is totally reflected onto the upper surface of the metal oxide film PS, which forms the septum walls SW3, not to be transmitted through the septum walls SW3. Therefore, the following possibility can be made lower in this modified example than Embodiment 1: a possibility that light radiated into the upper surface of the septum walls is received by the photodiode PD of each of the pixels. This matter makes it possible to prevent the generation of color mixing to improve the semiconductor device in performance.

In the present modified example, the metal film ME in the pixel region 1A is not covered with the insulator film IF2 (see FIG. 19), which is different in situation from the image pickup device described with reference to FIGS. 14 to 22. However, the surface of the metal film MF is subjected to passivation treatment to form the metal oxide film PS. Thus, the septum walls SW3 can be prevented from turning to an unstable oxide film. It is therefore possible to prevent the generation of noises in picked-up data by a matter that the film of the septum walls SW3 turns to an unstable film.

In the present modified example, the insulator film IF2 is not caused to remain in the pixel region 1A; thus, the width of the septum walls SW3 can be made smaller than that in the image pickup device described with reference to FIGS. 14 to 22.

Moreover, the liner film LF2 of the bottom between the adjacent septum walls SW3 is not covered with the insulator film IF2 since the insulator film IF2 is not caused to remain in the pixel region 1A. Accordingly, the number of entire stacked films between the color filters CF and the photodiodes PD can be decreased to prevent light radiated into the pixels from damping until the light reaches the photodiodes PD. In other words, the semiconductor device can be increased in optical transparency to be heightened in performance.

Herein, the process for manufacturing the image pickup device of the present modified example is compared with that for manufacturing the image pickup device described with reference to FIGS. 14 to 22. As has been described with reference to FIGS. 20 and 25, the step of subjecting the predetermined metal film to passivation treatment is performed in each of the two image-pickup-device-manufacturing processes. As a result, in the modified example, the above-mentioned advantageous effects can be gained without making the number of the manufacturing-process steps larger than that in the image-pickup-device-manufacturing process described with reference to FIGS. 14 to 22. Thus, an increase in semiconductor-device-manufacturing costs can be prevented.

### Embodiment 3

The present embodiment is an embodiment in which a metal film is buried into openings in a film and then septum walls including the metal film are formed, thereby attaining the formation of the septum walls easily with a high aspect ratio, which is different in situation from Embodiment 2. Hereinafter, with reference to FIGS. 28 to 40, a description will be made about a semiconductor device of the present embodiment, and a method for manufacturing this device. FIGS. 28 to 40 are each a cross section referred to for describing the method for manufacturing the semiconductor device of the present embodiment. FIG. 40 is a cross section illustrating an enlarged part of the semiconductor device of the embodiment.

In the process for manufacturing the semiconductor device of the embodiment, first, the same steps as described with reference to FIGS. 3 and 4 are performed to yield a structure illustrated in FIG. 28. In this embodiment, the interlayer dielectric film IL4 is formed with a larger thickness than that of the third interconnection layer.

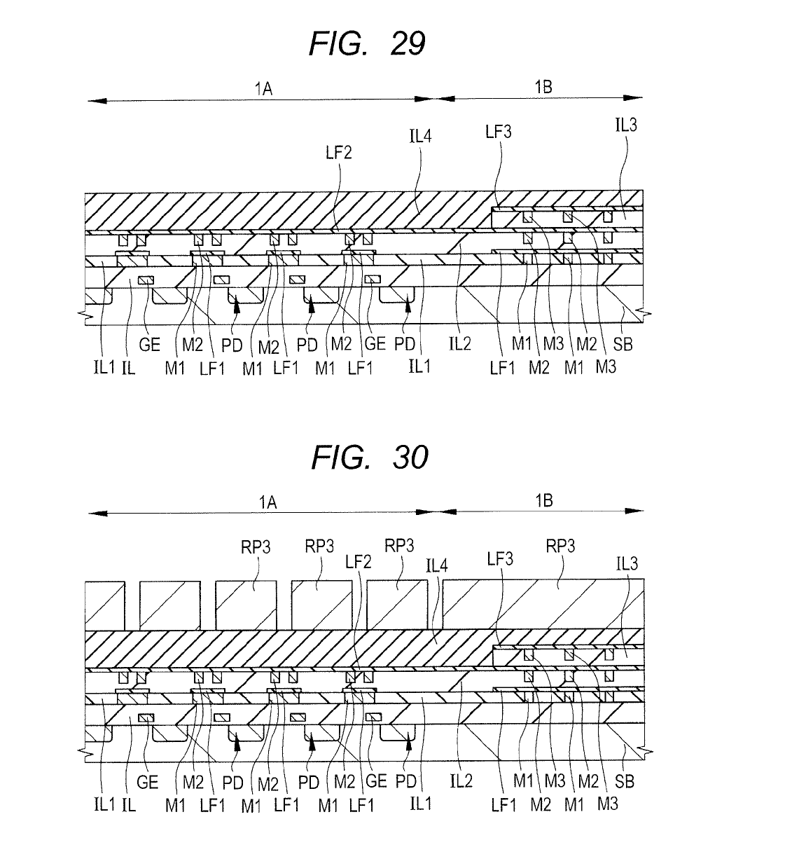

Next, as illustrated in FIG. 29, for example, a CMP method is used to make the upper surface of the interlayer dielectric film IL4 flat. At this time, the liner film LF3 is not made exposed from the interlayer dielectric film IL4.

Next, as illustrated in FIG. 30, a photolithographic technique is used to form a resist pattern RP3 on the interlayer dielectric film IL4. The resist pattern RP3 is a pattern for covering the peripheral circuit region 1B, and the pixels in the pixel region 1A. In the pixel region 1A, the region between the adjacent pixels is exposed from the resist pattern RP3.

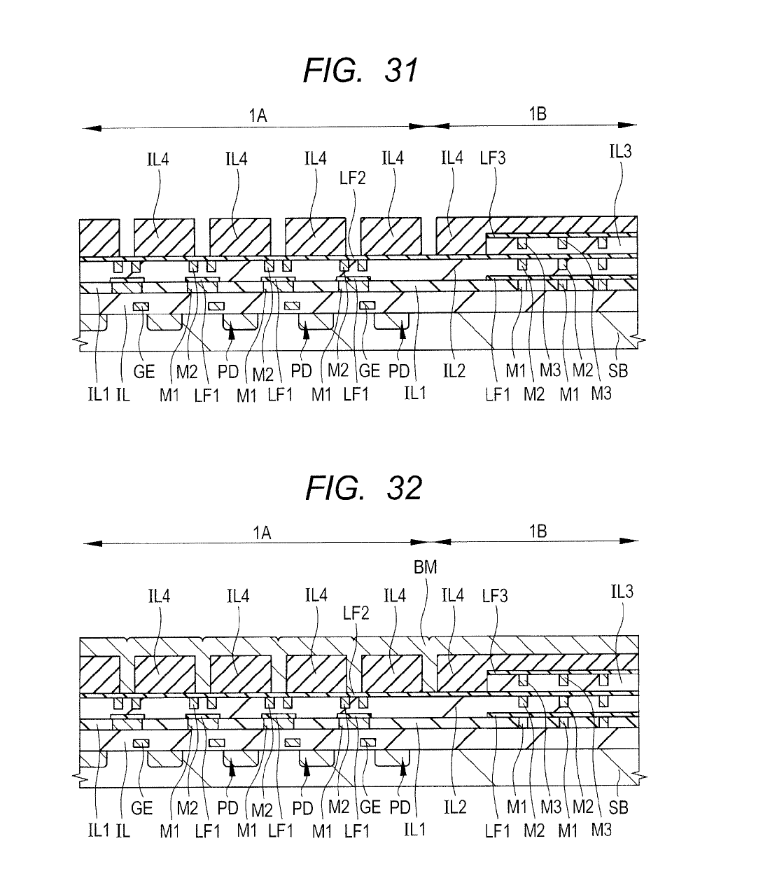

Next, as illustrated in FIG. 31, the resist pattern RP3 is used as a mask to perform dry etching, thereby removing the interlayer dielectric film IL4 in the pixel region 1A partially. In this way, the upper surface of the liner film LF2 in the region between the adjacent pixels is made exposed. In other words, in a region sandwiching, in a direction along the main surface of the semiconductor substrate SB, a region just above one of the photodiodes PD, that is, a region where each color filter is to be formed in a subsequent step, a trench is made which penetrates the interlayer dielectric film IL4. Thereafter, the resist pattern RP3 is removed. Through this process, plural trenches are made to have openings in the region between the pixels.

Next, as illustrated in FIG. 32, for example, a sputtering method, an electroplating method or some other to form a metal film BM on the semiconductor substrate SB. The metal film BM is a film which is made mainly of, for example, W (tungsten) or Cu (copper) and does not transmit light. The metal film BM is formed on the interlayer dielectric film IL4, and is also formed to be buried completely into the trenches opened to the interlayer dielectric film IL4.

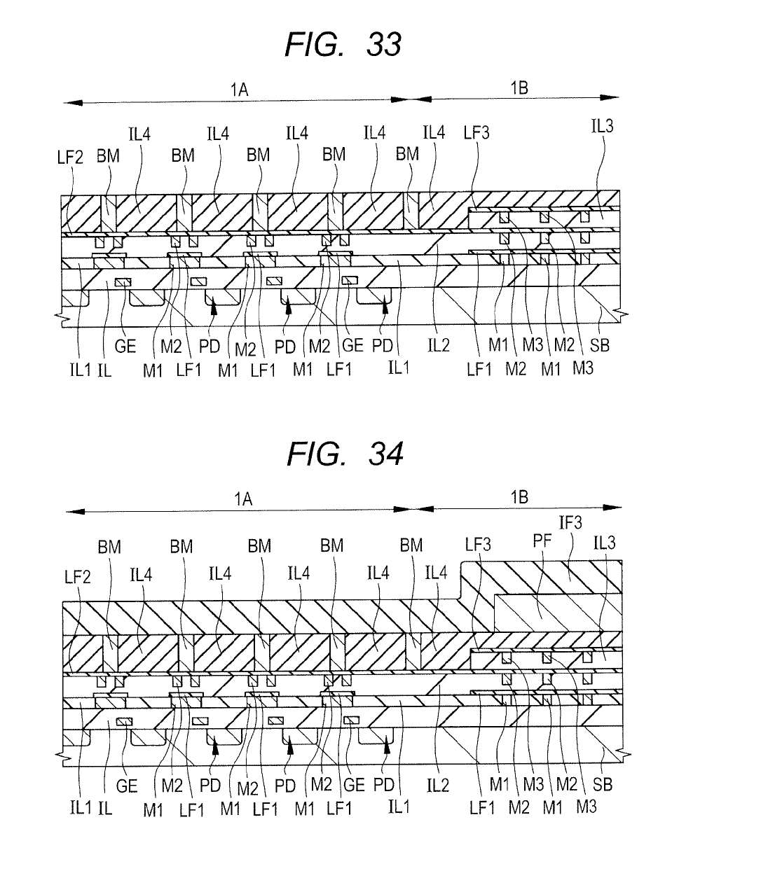

Next, as illustrated in FIG. 33, for example, a CMP method is used to polish the upper surface of the metal film BM, thereby making the upper surface of the interlayer dielectric film IL4 exposed. In this way, the metal film BM remains between the pixels to be only inside the trenches opened to the interlayer dielectric film IL4. This manner makes the metal film BM into the form of walls. In FIG. 33 is apparently illustrated a structure in which plural pieces of the metal film BM are arranged to be separated from each other. However, in plan view, the metal film BM has a lattice-form shape, so that the apparent pieces of the metal film BM illustrated in FIG. 33 are coupled and integrated with each other into a unity.

Next, as illustrated in FIG. 34, the same step as described with reference to FIG. 5 is performed to form a pad PF in the peripheral circuit region 1B. Thereafter, for example, a CVD method is used to form an insulator film IF3 on the semiconductor substrate SB. The insulator film IF3 is, for example, a silicon oxide film or silicon nitride film, and covers not only the upper surface of each of the metal film BM and the interlayer dielectric film IL4, but also the pad PF.

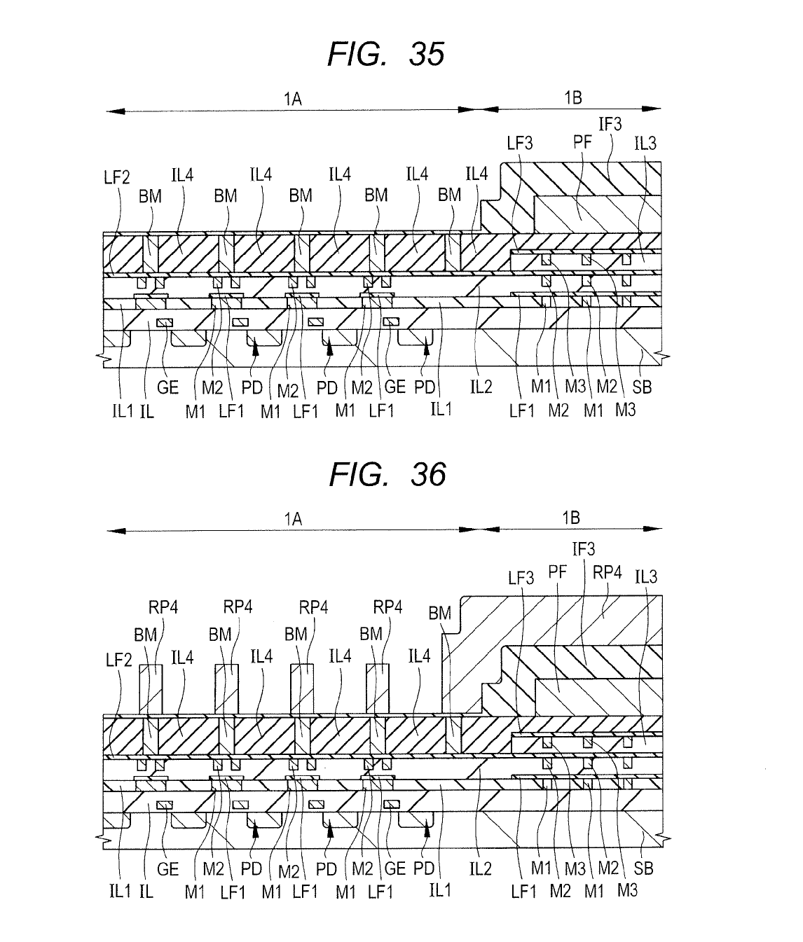

Next, as illustrated in FIG. 35, a photolithographic technique and an etching method are used to etch back the insulator film IF3 in the pixel region 1A, thereby making this film thin. At this time, the metal film BM is not exposed from the insulator film IF3.

Next, as illustrated in FIG. 36, a photolithographic technique is used to form a resist pattern RP4 on the insulator film IF3. The resist pattern RP4 is a pattern covering the peripheral circuit region 1B and is also a pattern from which the pixels in the pixel region 1A are exposed. In the pixel region 1A, the region between the adjacent pixels is covered with the resist pattern RP4. The width of the region between the adjacent pixels, which is covered with the resist pattern RP4, is larger than the width of the region between the adjacent pixels, which is exposed from the resist pattern RP3, in the step illustrated in FIG. 30.

In other words, as illustrated in FIG. 36, the resist pattern RP4 formed just above the metal film BM is larger in width than the metal film BM. That is to say, in plan view, side walls of the resist pattern RP4 are positioned outside the side walls of the pattern metal film BM.

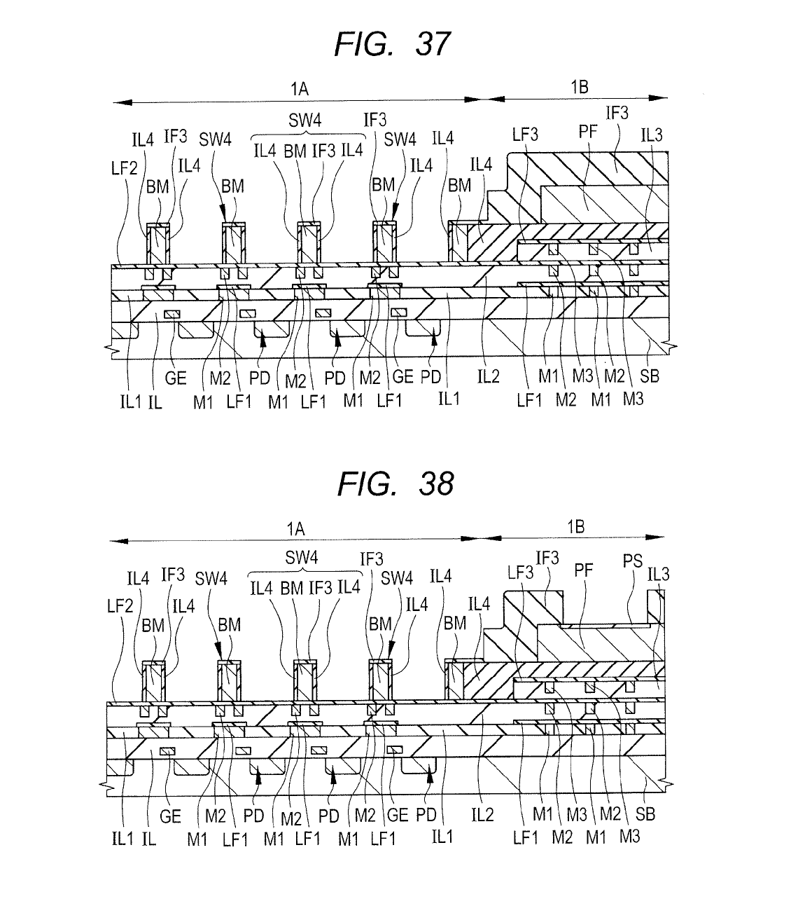

Next, as illustrated in FIG. 37, the resist pattern RP4 is used as a mask to perform dry etching, thereby removing the insulator film IF3 in the pixel region 1A partially and the interlayer dielectric film IL4 partially. That is to say, the insulator film IF3 and the interlayer dielectric film IL4 are removed in the regions where the color filters (referred to above also) are to be afterward formed. In this way, the upper surface of the liner film LF2 in each of the pixels is exposed. Thereafter, the resist pattern RP4 is removed. Through this step, in the pixel region 1A, there remain the insulator film IF3 covering the upper surface of the metal film BM, and the interlayer dielectric film IL4 covering the side walls of the metal film BM. The metal film BM, the insulator film IF3 being in contact with the upper surface of the metal film BM, and the interlayer dielectric film IL4 being in contact with the side walls of the metal film BM form septum walls SW4.

The regions between the adjacent septum walls SW4 are regions where the color filters are to be afterward formed. In the regions, neither the insulator film IF3 nor the interlayer dielectric film IL4 is formed. Through the process described hereinbefore, the septum walls SW4 are formed in the region between the adjacent pixels. The metal film BM is covered with the liner film LF2, the insulator film IF3, and the interlayer dielectric film IL4, so that the metal film BM can be prevented from begin oxidized into an unstable film.

Next, as illustrated in FIG. 38, a photolithographic technique and an etching method are used to remove the insulator film IF3 partially in the peripheral circuit region 1B, thereby making the upper surface of the pad PF exposed. Subsequently, passivation treatment is performed to form a metal oxide film PS onto the pad-PF-upper-surface made exposed from the insulator film IF3.

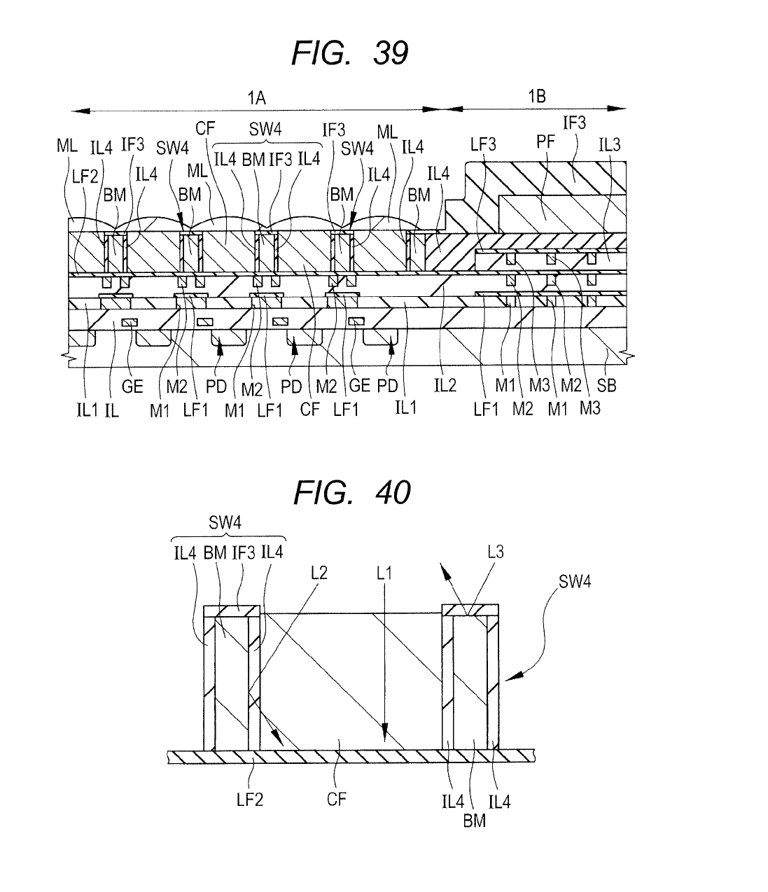

Next, as illustrated in FIG. 39, the same steps as described with reference to FIGS. 11 and 12 are performed to form the color filters CF (referred to above) between the adjacent septum walls SW4, and then a micro-lens ML is formed on each of the color filters CF. In this way, the semiconductor device of the present embodiment is completed.

In FIG. 40 is illustrated an enlarged cross section of any one of the color filters CF and the respective septum walls SW4 at both sides of the color filter CF. In the same manner as in FIG. 2, in FIG. 40, incident light rays L1 to L3 are illustrated. The incident light ray L1 is radiated into the upper surface of the color filter CF to reach one of the photodiodes without being radiated into the septum walls SW4. The incident ray L2 is radiated into the upper surface of the color filter CF, and then reflected onto side walls of the patterned metal film BM, which forms the septum walls SW4, to reach the photodiode. In other words, the metal film BM, which forms the septum walls SW4, reflects light totally; thus, the incident light ray L2 is totally reflected onto the side walls of the metal film BM to reach the photodiode just below the color filter CF.

The incident light ray L3 is radiated into the upper surface of the septum walls SW4. The incident light ray L3 is totally reflected onto the upper surface of the metal oxide film BM, which forms the septum walls SW4, not to be transmitted through the septum walls SW4. Therefore, the following possibility can be made lower in the present embodiment than Embodiment 1: a possibility that light radiated into the upper surface of the septum walls is received by the photodiode PD of each of the pixels. This matter makes it possible to prevent the generation of color mixing to improve the semiconductor device in performance.

As has been described with reference to FIGS. 30 to 33, in the present embodiment, the metal film BM is formed to be buried into the trenches opened to the interlayer dielectric film IL4, which is different in situation from Embodiment 2, in which the photolithographic technique and an etching method are used to pattern the metal film MF (see FIG. 17). When a photolithographic technique and an etching method are used to work a metal film, this metal film is not easily formed into a wall form with a high aspect ratio. When this metal film is made small in width, it is feared that the walls of the metal film collapse.

By contrast, in the present embodiment, the metal film BM is buried into the trenches to form the pattern of the metal film BM. According to this method, the metal film MF can be more easily formed as walls having a high aspect ratio than according to the method described just above. Accordingly, the septum walls SW4 can easily be made fine so that the respective light-receiving surfaces of the pixels can be enlarged. Thus, the semiconductor device can be improved in performance.

In the present embodiment, no insulator film IF2 (see FIG. 21) remains on the bottom of the color-filter-formed regions between the adjacent septum walls, which is different in situation from the image pickup device described with reference to FIGS. 14 to 21. In other words, as illustrated in FIG. 39, the liner film LF2 of the bottom between the adjacent septum walls SW4 is not covered with the insulator film IF2. Accordingly, the number of entire stacked films between the color filters CF and the photodiodes PD can be decreased to prevent light radiated into the pixels from damping until the light reaches the photodiodes PD. In other words, the semiconductor device can be increased in optical transparency to be heightened in performance.

### Embodiment 4

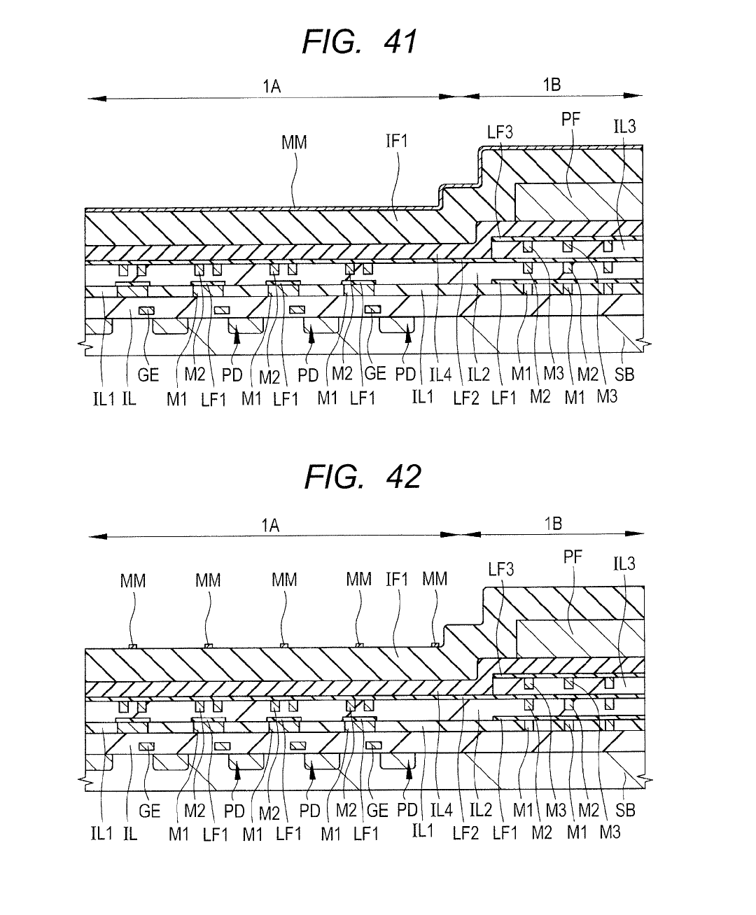

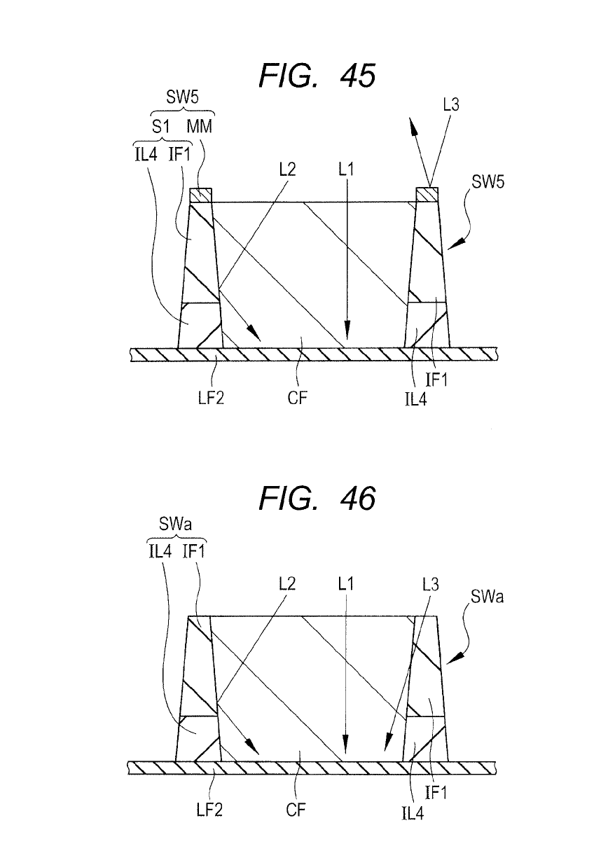

The present embodiment is an embodiment in which a film smaller in refractive index than color filters is used to form septum walls in the same manner as in the above-mentioned comparative example, but is different from the comparative example in that when this film is etch-worked to form the septum walls, a metal mask is used to cause the metal mask to remain as a part of the septum walls. Hereinafter, with reference to FIGS. 41 to 45, a description will be made about a semiconductor device of the present embodiment and a process for manufacturing the semiconductor device. FIGS. 41 to 44 are cross sections illustrating the method for manufacturing the semiconductor device of the embodiment. FIG. 45 is a cross section illustrating an image pickup device which is a modified example of the semiconductor device of the embodiment.

In the process for manufacturing the semiconductor device of the embodiment, first, the same steps as described with reference to FIGS. 3 to 6 are performed. As illustrated in FIG. 41, for example, a sputtering method is then used to form a metal film MM on the insulator film IF1. The metal film MM is, for example, a TiN (titanium nitride) film.

Next, as illustrated in FIG. 42, a photolithographic technique and an etching method are used to pattern the metal film MM. In this way, the metal film MM in the peripheral circuit region 1B is removed, and a pattern made of the metal film MM remains in the region between adjacent pixels in the pixel region 1A. In short, in the peripheral circuit region 1B and the pixels, the upper surface of the insulator film IF1 is exposed.

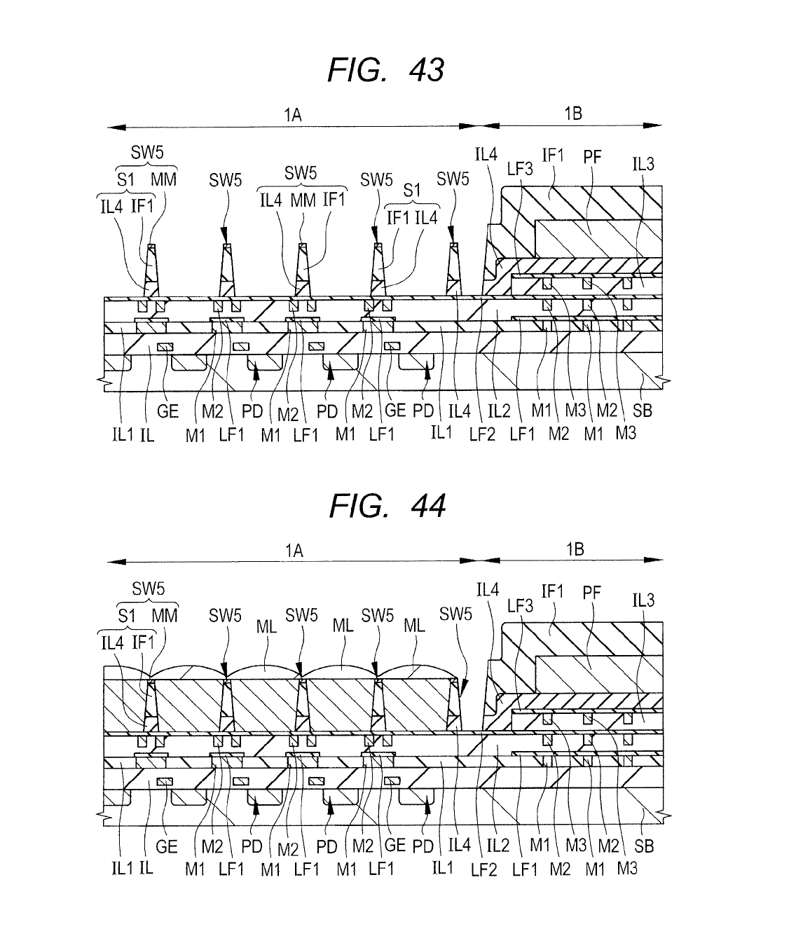

Next, as illustrated in FIG. 43, the metal film MM is used as a hard mask to perform dry etching, thereby removing the insulator film IF1 and the interlayer dielectric film IL4 partially. In this etching step, the peripheral circuit region 1B is covered with a resist pattern (not illustrated), and this resist pattern is used as a mask. Thereafter, this resist pattern is removed.

Through this step, in the individual pixels, the upper surface of the liner film LF2 is exposed. In this way, between the above-mentioned adjacent pixels, septum walls SW5 are formed which are made of the interlayer dielectric film IL4, the insulator film IF1 and the metal film MM, which are successively formed on the liner film LF2. The interlayer dielectric film IL4 which is, for example, a silicon oxide film, and the insulator film IF1, which is formed on the interlayer dielectric film IL4 and is, for example, a silicon oxide film, form an insulator film S1. The septum walls SW5 are made of the insulator film S1 and the metal film MM stacked on the insulator film S1.

Next, the steps described with reference to FIGS. 10 to 12 are performed to complete semiconductor device of the present embodiment, which is illustrated in FIG. 44.

In FIG. 45 is illustrated an enlarged cross section of one of the color filters CF and the respective septum walls SW5 at both sides of the color filter CF. In the same manner as in FIG. 2, in FIG. 45, incident light rays L1 to L3 are shown. The incident light ray L1 is radiated into the upper surface of the color filter CF to reach one of the photodiodes without being radiated into the septum walls SW5. The incident ray L2 is radiated into the upper surface of the color filter CF, and then reflected onto side walls of the septum walls SW5 to reach the photodiode. In other words, the insulator film S1, which forms the septum walls SW5, is made of a material smaller in refractive index than the color filter CF; thus, the incident light ray L2 is totally reflected onto the side walls of the patterned insulator film S1 to reach the photodiode just below the color filter CF. The metal film MM is a film which does not transmit light, so that light radiated into side walls of the patterned metal film MM is totally reflected to reach the photodiode.

The incident light ray L3 is radiated into the upper surface of the septum walls SW5. The incident light ray L3 is totally reflected onto the upper surface of the metal film MM, which forms the septum walls SW5, not to be transmitted through the septum walls 5. Therefore, the following possibility can be made lower in this embodiment than in Embodiment 1: a possibility that light radiated into the upper surface of the septum walls is received by the photodiode PD of each of the pixels. This matter makes it possible to prevent the generation of color mixing to improve the semiconductor device in performance.

When the patterning is performed, the metal film, such as a TiN (titanium nitride) film, is used as a metal mask, a fine pattern can be formed with a high precision. In conclusion, it is conceivable that when a semiconductor device is made fine, etching is performed using, as a hard mask, a pattern made of a metal film, as performed in the present embodiment.

When patterning is performed as a metal mask, it is conceivable that the metal mask is removed after an etching step using the metal mask. In the present embodiment, the septum walls SW5 are members located to shield light. It is therefore unnecessary to perform the step of removing the metal film MM, which is the metal mask on the insulator film S1, after the formation of the insulator film S1 by patterning.

In this embodiment, the metal film MM is caused to remain on the septum walls SW5. It is therefore unnecessary to remove the metal film MM after the step illustrated in FIG. 43. Accordingly, the semiconductor-device-manufacturing process can be made simple. Furthermore, as described above with reference to FIG. 45, by causing the metal film MM to remain on the septum walls SW5, light radiated into the upper surface of the septum walls SW5 can be prevented from invading the inside of the septum walls SW5, and the pixels.

The above has specifically described the present invention made by the inventors byway of embodiments thereof. However, of course, the invention is not limited to the embodiments. The embodiments may be modified into various form as far as the modified embodiments do not depart from the subject matters thereof.

The contents described as the embodiments are partially recited as the following supplementary statements 1 to 11:

[1] A semiconductor device, including:

a semiconductor substrate;

a photoelectric transducer which receives light to generate a signal electric charge; and

a plurality of septum walls formed over the photoelectric transducer;

wherein a region between the adjacent septum walls adjacent to each other in a direction along a main surface of the semiconductor substrate, is a first region where a first film is formed, the first film being a film that transmits light to be radiated into the photoelectric transducer;

wherein each of the septum walls includes a second film, and a metal film covering the second film; and

wherein the first film is larger in refractive index than the second film.

[2] The semiconductor device according to Item 1,

wherein the first film is formed in the first region.

[3] The semiconductor device according to Item 1,

wherein the first film is a color filter.

[4] A method for manufacturing a semiconductor device, including the steps of:

(a1) forming, in a semiconductor substrate, a photoelectric transducer which receives light to generate a signal electric charge;

(b1) forming a metal film covering the upper surface of the photoelectric transducer; and

(c1) removing the metal film selectively in a first region which is just above the photoelectric transducer and is further a region where a first film that transmits the light to be radiated into the photoelectric transducer is to be formed, thereby making the photoelectric transducer exposed from the metal film;

wherein each metal film that sandwich the first region is configured to form septum walls.

[5] The method for manufacturing a semiconductor device according to Item 4,

further including, after the step (c1), the step (d1) of forming the first film in the first region.

[6] The method for manufacturing a semiconductor device according to Item 4,

further including, after the step (c1), the steps of:

(e1) forming a first insulator film over the semiconductor substrate to cover the metal film, which sandwiches the first region; and

(f1) making the first insulator film covering the metal film into a thin film,

wherein the septum walls include the metal film, and the first insulator film covering the upper surface and side walls of the metal film.

[7] The method for manufacturing a semiconductor device according to Item 4,

wherein the semiconductor substrate includes a second region and a third region arranged along the main surface of the semiconductor substrate,

wherein in the step (a1), the photoelectric transducer is formed in the semiconductor substrate in the second region,

wherein in the step (c1), the metal film in the first region and the metal film in the third region are removed to form a pad including the metal film in the third region,

the method further including the steps of:

(e2) forming, after the step (c1), a first insulator film over the semiconductor substrate to cover each metal film sandwiching the first region, and the pad;

(f2) removing the first insulator film in the second region, and the first insulator film in a part of the third region to make the metal film in the second region, and the upper surface of the pad exposed; and

(g1) subjecting a part of the outer surface of each of the metal film and the pad to passivating treatment to form a second insulator film covering the upper surface and side walls of the metal film, and a third film covering the upper surface of the pad;

the septum walls including the metal film in the second region, and the second insulator film covering the metal film in the second region.

[8] A method for manufacturing a semiconductor substrate, including the steps of:

(a1) forming, in a semiconductor substrate, a photoelectric transducer which receives light to generate a signal electric charge;

(b1) forming a second film covering the upper surface of the photoelectric transducer;

(c1) in a direction along a main surface of the semiconductor substrate, forming a trench penetrating the second film, in a region just above the photoelectric transducer and where a first region in which a first film that transmits light to be radiated into the photoelectric transducer is to be formed is sandwiched;

(d1) forming a metal film to be buried into the trenches, and subsequently making the upper surface of the metal film and the upper surface of the second film flat;

(e1) forming a third film covering the upper surface of the metal film; and

(f1) removing the third film and the second film in the first region to form septum walls each including the metal film, the second film covering side walls of the metal film, and the third film covering the upper surface of the metal film.

[9] The method for manufacturing a semiconductor according to Item 8,

further including, after the step (f1), the step (g1) of forming the first film in the first region.

[10] A method for manufacturing a semiconductor device, including the steps of:

(a1) forming, in a semiconductor substrate, a photoelectric transducer which receives light to generate a signal electric charge;

(b1) forming a second film covering the upper surface of the photoelectric transducer;

(c1) forming a pattern including a metal film over the second film to sandwich, in a direction along a main surface of the semiconductor substrate, a first region which is just above the photoelectric transducer and is a region where a first film that transmits light to be radiated into the photoelectric transducer is to be formed; and

(d1) using the pattern as a mask to work the second film to remove the second film in the first region, thereby forming septum walls including the second film and the pattern covering the upper surface of the second film;

the first film being larger in refractive index than the second film.

[11] The method for manufacturing a semiconductor device according to Item 10,

further including, after the step (d1), the step (e1) of forming the first film in the first region.

What is claimed is:

1. A semiconductor device, comprising:
a semiconductor substrate;
a photoelectric transducer which is formed over the semiconductor substrate, and receives light to generate a signal electric charge; and
a plurality of septum walls formed over the photoelectric transducer,
wherein a region between the adjacent septum walls adjacent to each other in a direction along a main surface of the semiconductor substrate is a first region where a first film is formed, the first film being a film that transmits light to be radiated into the photoelectric transducer,
wherein each of the septum walls comprises a second film, and a third film formed between a side wall of the second film, and the first region,
wherein the third film is larger in refractive index than the first film, and
wherein the first film is larger in refractive index than the second film.

2. The semiconductor device according to claim 1,
wherein the first film is formed in the first region.

3. The semiconductor device according to claim 1,
wherein the first film is a color filter.

4. The semiconductor device according to claim 1,
wherein the second film is a silicon oxide film, and
wherein the third film is a silicon nitride film.

5. The semiconductor device according to claim 1,
wherein an optical waveguide is formed between the first region and the photoelectric transducer.

6. The semiconductor device according to claim 5,
wherein the third film is formed between the first region and the optical waveguide, and
wherein the upper surface of the second film is covered with the third film.

7. The semiconductor device according to claim 1,
wherein the photoelectric transducer does not overlap with the septum walls in plan view.

8. A method for manufacturing a semiconductor device, comprising the steps of:
(a1) forming, over a semiconductor substrate, a photoelectric transducer which receives light to generate a signal electric charge;
(b1) forming a plurality of second films which sandwich, in a direction along a main surface of the semiconductor substrate, a first region which is just above the photoelectric transducer and is a region where a first film that transmits light to be radiated to the photoelectric transducer is to be formed;
(c1) forming a third film covering side surfaces of the second film between the first region, and the adjacent second films adjacent to each other,
thereby forming septum walls including the second film, and the third film being in contact with the side walls of the second film,
the third film being larger in refractive index than the first film, and
the first film being larger in refractive index than the second film.

9. The method for manufacturing a semiconductor device according to claim 8, further comprising a step of
(d1) after the step (c1), forming the first film in the first region.

10. The method for manufacturing a semiconductor device according to claim 8,
wherein the first film is a color filter.

11. The method for manufacturing a semiconductor device according to claim 8,
wherein the second film is a silicon oxide film, and
wherein the third film is a silicon nitride film.

12. The method for manufacturing a semiconductor device according to claim 8, comprising a step of:
(a2) before the step (b1), forming an optical waveguide between the photoelectric transducer and the first region.

13. The method for manufacturing a semiconductor device according to claim 12,
wherein the third film is formed in the step (c1) to cover the upper surface and the side walls of the second film, and the upper surface of the optical waveguide,
wherein the third film is formed between the first region and the optical waveguide, and
wherein the upper surface of the second film is covered with the third film.
